(19) United States
(12) Patent Application Publication
(10) Pub. No.: US 2024/0337956 A1
(43) Pub. Date: Oct. 10, 2024

(54) APPARATUS AND METHOD FOR PREPARING AND CLEANING A COMPONENT

(71) Applicant: ASML NETHERLANDS B.V., Veldhoven (NL)

(72) Inventors: Lucas Christiaan Johan HEIJMANS, Eindhoven (NL); Imre Rudolf Richard DEHNER, Eindhoven (NL); Raymond Wilhelmus Louis LAFARRE, Helmond (NL); Cornelis Christiaan OTTENS, Veldhoven (NL); Marcus Adrianus VAN DE KERKHOF, Helmond (NL); Andrey NIKIPELOV, Eindhoven (NL); Dennis VANOTTERDIJK, Houthalen (BE); Edwin Johannes Theodorus SMULDERS, Nuenen (NL); Andrei Mikhailovich YAKUNIN, Veldhoven (NL); Guido SALMASO, Eindhoven (NL); Luc VOORDECKERS, Scherpenheuvel-Zichem (BE); Chaitanya Krishna ANDE, Eindhoven (NL); Martinus Jacobus Johannes COENEN, Veldhoven (NL)

(73) Assignee: ASML NETHERLANDS B.V., Veldhoven (NL)

(21) Appl. No.: 18/578,780

(22) PCT Filed: Jul. 8, 2022
(86) PCT No.: PCT/EP2022/069063

§ 371 Date: Jan. 12, 2024

(30) Foreign Application Priority Data
Aug. 6, 2021 (EP) 21190107.9
Aug. 18, 2021 (EP) 21191923.8

(51) Int. Cl. G03F 7/00; G03F 1/62

(52) U.S. Cl. CPC G03F 7/70925; G03F 7/70708; G03F 7/7085; G03F 7/70875; G03F 1/62

(57) ABSTRACT

An apparatus for cleaning a component for use in a lithographic apparatus, the apparatus including at least one cleaning module or a plurality of cleaning modules, wherein the at least one cleaning module or the plurality of cleaning modules include a plurality of cleaning mechanisms, and wherein the plurality of cleaning mechanisms include: at least one preparing mechanism for reducing adhesion of the particles to the component and at least one removing mechanism for removing particles from the component, or a plurality of removing mechanisms for removing particles from the component.

### CROSS-REFERENCE TO RELATED APPLICATIONS

This application claims priority of EP application 21190107.9 which was filed on Aug. 6, 2021 and EP application Ser. No. 21191923.8 which was filed on Aug. 18, 2021 which are incorporated herein in its entirety by reference.

### FIELD

The present invention relates to an apparatus and method for preparing and/or cleaning a component for a lithographic apparatus. More particularly, the component is a pellicle.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern at a patterning device (e.g., a mask) onto a layer of radiation-sensitive material (resist) provided on a substrate.

To project a pattern on a substrate a lithographic apparatus may use electromagnetic radiation. The wavelength of this radiation determines the minimum size of features which can be formed on the substrate. A lithographic apparatus, which uses extreme ultraviolet (EUV) radiation, having a wavelength within the range 4-20 nm, for example 6.7 nm or 13.5 nm, may be used to form smaller features on a substrate than a lithographic apparatus which uses, for example, radiation with a wavelength of 193 nm.

The use of pellicles in lithography is well-known and well-established. In use, a pellicle is placed in front of the patterning device (reticle). This may protect the reticle from contamination from the lithographic apparatus, but adds possible contamination from the pellicle itself. Since the pellicle is very close to the reticle (˜2 mm), any contamination on it is a big risk for reticle defectivity. Therefore, a clean surface of the pellicle is very important for the viability of any pellicle.

A typical pellicle in a DUV or EUV lithographic apparatus is a membrane which is located away from the patterning device and is out of the focal plane of a lithographic apparatus in use. Because the pellicle is out of the focal plane of the lithographic apparatus, contamination particles which land on the pellicle are out of focus in the lithographic apparatus. Consequently, images of the contamination particles are not projected onto the substrate. If the pellicle were not present, then a contamination particle which landed on the patterning device would be projected onto the substrate and would introduce a defect into the projected pattern.

It may be desirable to use a pellicle in an EUV lithographic apparatus. EUV lithography differs from DUV lithography in that it is typically performed in a vacuum and the patterning device is typically reflective rather than being transmissive. A pellicle may be called a membrane.

Pellicles are produced under extremely clean conditions. However, they may still contain contaminating particles. Each of these particles is a risk and can become a defectivity issue if it releases from the pellicle and transfers from the pellicle backside to the patterning device (reticle) frontside in a lithographic apparatus. These contamination particles may cause defects to print resulting in consequential productivity loss.

It is desirable to provide an apparatus and method for cleaning a pellicle (i.e. removing particles before the pellicle goes into the lithographic apparatus) which overcomes or mitigates one or more problems associated with the prior art. Examples of the invention which are described herein may have use for an EUV lithographic apparatus. Examples of the invention may also have use for a DUV lithographic apparatus and/or another form of lithographic tool.

### SUMMARY

According to a first aspect of the invention, there is provided an apparatus for cleaning a component for use in a lithographic apparatus, the apparatus comprising at least one cleaning module or a plurality of cleaning modules, wherein the at least one cleaning module or the plurality of cleaning modules comprise a plurality of cleaning mechanisms, and wherein the plurality of cleaning mechanisms comprise: at least one preparing mechanism for reducing adhesion of the particles to the component and at least one removing mechanism for removing particles from the component, or a plurality of removing mechanisms for removing particles from the component.

This may have an advantage of removing a substantial amount, most or all of the particles that may be released in the lithographic apparatus LA. The apparatus may more effectively clean the component (i.e. remove more particles and/or do so in a quicker time) than other previous methods. Using a plurality of cleaning mechanisms has an advantage that more or different particles may be cleaned than may be possible using a single cleaning mechanism (or stressor).

Cleaning a component may include both preparing for removing particles (e.g. reducing adhesion of particles to the component) and removing particles (from the component).

The preparing mechanism may be used before the removing mechanism, i.e. they may be used sequentially. The preparing mechanism and the removing mechanism may be used at the same time, i.e. reducing the adhesion of the particles to the component and removing the particles from the component may be simultaneous.

The at least one cleaning module may comprise a plurality of cleaning mechanisms. The plurality of cleaning modules together may comprise a plurality of cleaning mechanisms, i.e. one cleaning module may comprise one cleaning mechanism and another cleaning module may comprise another cleaning mechanism. One or more of the cleaning modules may each comprise a plurality of cleaning mechanisms.

The apparatus may comprise the plurality of cleaning modules and the apparatus may be configured such that the component may be passable through the plurality of cleaning modules sequentially to be cleaned.

The cleaning module or cleaning modules may comprise at least one separation module for removing particles from the component.

The apparatus may comprise a robot module for moving the components between modules.

The apparatus may comprise a part (e.g. pellicle) library module comprising a plurality of parts.

The apparatus may comprise a vacuum chamber module for separating vacuum inside the apparatus from outside the apparatus.

The separation module may be for reducing adhesion of particles to the component, either during or before removing the particles from the component. This means that the efficiency of removing the particles may be increased.

The cleaning modules may comprise: a plurality of separation modules, and/or at least one separation module and at least one preparation module for reducing adhesion of particles to the component.

The cleaning module or cleaning modules may be maintained under a vacuum or controlled gas environment.

The vacuum or controlled gas environment may be maintained between cleaning modules (e.g. from the preparation module to the separation module so that the adhesion reduction may be maintained and so that more particles may not go onto the component). The controlled gas environment may have a predetermined gas/pressure/temperature. The component may be transferred between cleaning modules under the vacuum or controlled gas environment.

The removing mechanism and/or the preparing mechanism may comprise a vacuum generating mechanism.

The vacuum produced by the vacuum generating mechanism may at least assist in reducing adhesion of the particles to the component or removing the particles from the component.

The preparing mechanism may comprise a heat generating mechanism configured to generate heat to dry the component and/or the particles in a vacuum environment.

Water vapor or other oxygen-containing gasses pressure in the vacuum environment may have a pressure of at least one of: below 1E-4 Pa, below 1E-5 Pa, below 1E-6 Pa, or below 1E-7 Pa.

The heat generating mechanism may comprise a radiative heater.

The heat generating mechanism may be configured such that the radiative heat towards a border of the component may be below 1 W/cm2 and/or the border may be in contact with a heat sink such that the border temperature remains below 400 C.

The radiative heater may be a laser or an IR lamp. The laser may have a wavelength in the range of 0.5-5 μm. The component may be heated all at once or in segment by segment.

Radiative heat power density at the component may be below 10 W/cm², preferably in a range of 1-5 W/cm² or 2-5 W/cm². The radiative heater may be configured to have a power density in a range of 1-5 W/cm² at the component applied for a range of 0.1-1000 seconds or 10-1000 seconds.

The preparing mechanism may comprise a plasma generating mechanism for generating a plasma adjacent to or around the component. This may promote water outgassing, including water trapped in and around the particles. This may change the composition and/or roughness of the particles.

The plasma generating mechanism may be configured to generate plasma with at least one of: a reducing agent, hydrogen, a noble gas, a reducing agent and an oxidizing agent, and/or hydrogen and water.

The ratio between reducing agent and oxidizing agent may be greater than 100, preferably may be greater than 1000. The reducing agent concentration may be relatively much higher than the concentration of the oxidizing agent. This may be to ensure that the mechanical properties (strength and tension) and optical properties (transmission and reflection) of the component (e.g. a pellicle) are maintained. The reducing agent concentration may be 1000 times higher than the concentration of the oxidizing agent.

The plasma generating mechanism may be configured to generate plasma with a power dissipation to the component in a range of 1 mW/cm2 to 1 W/cm2.

The preparing mechanism may comprise an electron beam generating mechanism for generating an electron beam to be incident on the side of the component having the particles to be removed.

The electron beam generating mechanism may be configured to generate the electron beam in an environment including at least one of: a reducing agent, hydrogen, a reducing agent and an oxidizing agent, and/or hydrogen and water.

The ratio between reducing agent and oxidizing agent may be greater than 100, preferably may be greater than 1000.

Pressure for plasma generation may be in the range of 0.01 Pa to 100 Pa, preferably may be in the range of 0.1 Pa to 10 Pa.

The environment may have a pressure in a range of 0.01 Pa to 10 Pa.

The electron beam generating mechanism may be configured to have an energy in a range of 30-3000 eV, the current density at the component may be in a range 10 uA/cm2 to 10 mA/cm2, and/or the power dissipation at the component may be below 1 W/cm2.

The preparing mechanism may comprise a VUV or EUV photon generating mechanism for generating VUV or EUV photons to be incident on the component.

The VUV or EUV photon generating mechanism may be configured to generate the VUV or EUV photons in an environment including at least one of: a reducing agent, hydrogen, a reducing agent and an oxidizing agent, and/or hydrogen and water.

The VUV or EUV photon generating mechanism may be configured to generate VUV or EUV photons with a power dissipation to the component below 1 W/cm2.

The preparing mechanism may comprise a radical generating mechanism for generating hydrogen radicals adjacent to or around the component.

The radical generating mechanism may comprise at least one of a plasma generating mechanism and/or a hot filament.

The removing mechanism may comprise a vibration generating mechanism for generating mechanical oscillations in the component.

The vibration generating mechanism may comprise at least one excitation electrode; and a mechanism for applying a time-varying voltage across the at least one excitation electrode and the component.

The removing mechanism may comprise a VUV photon generating mechanism for generating VUV photons to be incident on the component.

The VUV light may have wavelengths in the range 20-200 nm (62 eV-6.2 eV).

The VUV photons may charge the particles and the component.

The VUV photons may be incident on the surface of the component to be cleaned (e.g. the reticle facing side of a pellicle) or the opposite surface of the component (e.g. VUV light may be through the pellicle). The light being incident on the opposite surface to be cleaned of the component may lead to increased ionization between particles and the component, thus maximizing the repulsion and cleaning effect.

The VUV photon generating mechanism may be configured to generate a VUV photon beam for illuminating substantially the whole surface of the component at once or part of the surface and wherein the VUV photon beam may be scannable to illuminate the whole surface of the component.

The removing mechanism may comprise a plasma generating mechanism for generating a plasma adjacent to or around the component.

The plasma may charge the particles. The plasma/gas flow may give a kick to the particles.

The removing mechanism may comprise a heat generating mechanism for inducing particle transfer away from the component.

The heat generating mechanism may be a laser.

The removing mechanism may comprise an electric field generating mechanism for transporting particles away from the component.

The electric field generating mechanism may comprise a collector electrode; and a mechanism for applying a voltage across the component and the collector electrode.

There may be two collector electrodes.

The component may be removed with the particles stuck to the collector electrode. This may be so that the particles cannot return to the component when the power to the collector electrode is turned off.

The collector electrode may comprise a plate covering substantially all of the component or a grid of electrodes.

The apparatus may comprise one or more shields configured to prevent particles from returning to the component when power supply to the collector electrode is turned off.

The shields may be retractable.

The removing mechanism may comprise an electron beam generating mechanism for generating an electron beam to be incident on the side of the component having the particles to be removed.

The electron beam generating mechanism may be configured to produce the electron beam with an energy of over 80 eV.

The electron beam generating mechanism may be configured such that the electron beam is pulsed.

The electron beam is combined with plasma. The electron beam (pulsed or continuous) may be incident on the component at the same time as the plasma source (plasma generating mechanism) provides plasma (may be pulsed or continuous). Plasma and electrons from the electron beam may be present at the component simultaneously or alternating.

The electron beam generating mechanism may comprise a scanning electron microscope for imaging the particles and/or the component.

The apparatus may comprise at least one displacement sensor for measuring a displacement of the component relative to the component at rest; and a controller operable to determine if the measured displacement of the component is outside a predetermined range and control the mechanism for applying the time-varying electric field to alter at least one characteristic of the time-varying electric field if the measured displacement of the component is outside the predetermined range.

The displacement may be dynamic and correspond to low eigenmodes of the film under tension within the component.

The apparatus may be configured such that one or more additional cleaning modules may be added to the apparatus.

The component may be at least one of a pellicle, an EUV transparent film, a dynamic gas lock membrane, or an EUV spectral purity filter.

Membranes (e.g. pellicles) may be damaged during membrane cleaning. In particular, when inducing mechanical oscillations in the membrane using a time-varying electric field generator (e.g. at least one electrode), a run-away failure may occur wherein a stiffness of the membrane is unable to resist an electrostatic force generated by the electrode. In this case, the membrane deforms until the membrane touches the electrode and is damaged.

Even with the two electrodes exerting approximately equal pressure on opposite sides of membrane, run-away failure is a risk. The membrane exerts a force (F_{spring}) [N] that resists instantaneous deformation (h) [mm] with a stiffness coefficient (k) [N/mm] according to the following equation:

$$\\ {F}_{spring} = - kh .$$

The stiffness coefficient (k) may be in a range of 110-100 N30 N/mm, typically 10 N/mm. The electrostatic forces generated by the two electrodes becomes unstable if the deformation (h) becomes comparable to a gap between the membrane and one of the electrodes. If the electrostatic forces generated by the two electrodes becomes unbalanced (e.g. unstable), run-away failure occurs.

The smaller the gap between the membrane and the electrodes, the greater the risk of the electrostatic forces generated by the two electrodes becoming unbalanced. Also, the larger the electrodes, the greater the risk of the electrostatic forces generated by the two electrodes becoming unbalanced. This greater sensitivity to the electrostatic forces generated by the two electrodes becoming unbalanced results from pressure scaling with the electric field squared, so with the inverse squared gap between the membrane and the electrodes. This relationship is described in the following equation:

$$\\ {F}_{electrode} = {P}_{nom} * S * {H}^{{}_{} 2} ( \frac{1}{{( H - h )}^{2}} - \frac{1}{{( H + h )}^{2}} ) ,$$

where: F_{electrode} is the force exerted on the membrane by one of the electrodes [N]; Pₙₒₘ is the pressure upon the membrane when the membrane is equidistant between the first electrode and the second electrode (and the membrane is flat) [N/mm²]; S is a cross-section of the electrodes [mm²]; H is a position of the membrane at rest [mm]; and h is the deviation of the membrane position from the position of the membrane at rest [mm] (at the projection of the electrodes).

If F_{electrode}>F_{spring}, then the membrane stiffness cannot resist the attraction to the closest of the electrodes, and the membrane deforms until it touches one of the electrodes, causing the membrane to fail.

The present disclosure therefore aims to provide a method and apparatus for removing particles from a membrane, which at least reduces the risk of run-away failure of the membrane.

According to a second aspect of the invention, there is provided a membrane cleaning apparatus for removing particles from a membrane, the apparatus comprising: a membrane support for supporting the membrane; a time-varying electric field generator for inducing mechanical oscillations in the membrane when supported by the membrane support, to remove particles from the membrane; at least one displacement sensor for measuring a displacement of the membrane relative to the membrane at rest when supported by the membrane support; and a controller operable to determine if the measured displacement of the membrane is outside a predetermined range and control the time-varying electric field generator to alter at least one characteristic of the time-varying electric field if the measured displacement of the membrane is outside the predetermined range.

Advantageously, the membrane cleaning apparatus for removing particles from a membrane reduces the risk of run-away failure of the membrane. Advantageously, the membrane cleaning apparatus for removing particles from the membrane enables a field strength of the time-varying electric field generated by at least one electrode to be increased (e.g. to improve particle removal) without the risk of run-away failure of the membrane. Advantageously, the membrane cleaning apparatus for removing particles from the membrane enables the at least one electrode to be positioned closer to the membrane (e.g. to improve particle removal) without the risk of run-away failure of the membrane.

The membrane may comprise a pellicle.

The at least one displacement sensor may measure the displacement of the membrane substantially as frequently as a frequency of at least one of the following low mechanical oscillation eigenmodes of the membrane: mode 1 (e.g. lowest mode, monopole), mode 2 (e.g. dipole, long side), mode 3 (e.g. dipole, short side), mode 4 (e.g. quadrupole), and other low frequency eigenmodes.

Advantageously, measuring the displacement of the membrane substantially as frequently as a frequency of at least one of the low frequency eigenmodes enables fewer displacement sensors (e.g. proximity sensors) to be used.

The at least one displacement sensor may measure the displacement of the membrane more frequently than at least one of: 100 Hz, 1000 Hz, 10,000 Hz.

The at least one displacement sensor may measure the displacement of the membrane less frequently than at least one of: 1000 Hz, 10,000 Hz, 100,000 Hz.

The at least one displacement sensor may measure the displacement of the membrane more frequently than a frequency of at least one of the following low mechanical oscillation eigenmodes of the membrane: mode 1 (e.g. lowest mode, monopole), mode 2 (e.g. dipole, long side), mode 3 (e.g. dipole, short side), mode 4 (e.g. quadrupole).

Advantageously, measuring the displacement of the membrane more frequently than the low frequency eigenmodes enables better determination of at least one of an amplitude, frequency, phase of the mechanical oscillations of the membrane.

The predetermined displacement range may comprise displacement of at least a localized portion of the membrane relative to the membrane at rest, with a smaller magnitude than at least one of: 10 μm, 100 μm, 1000 μm.

The at least one displacement sensor may be configured to measure a displacement of at least a localized portion of the membrane relative to the localized portion of the membrane at rest.

A first displacement sensor may be configured to measure a displacement proximate to a first excitation electrode of a localized portion of the membrane relative to the localized portion of the membrane at rest; and a second displacement sensor may be configured to measure a displacement proximate to a second excitation electrode of a localized portion of the membrane relative to the localized portion of the membrane at rest.

In use, the electrodes may be positioned equidistant from the membrane. Having the electrodes equidistant from the membrane enables an excitation of the membrane to be balanced. For example, while active, the electrodes exert force on the membrane in opposite directions and a time-averaged force on the membrane from the electrodes combined is less than 10% (e.g. preferably less than 1%) of a time-averaged force from any one of the electrodes.

The controller may be operable to determine if the measured displacement of the membrane is outside the predetermined range based on a measured maximum displacement of the membrane.

The controller may be operable to control the time-varying electric field generator to reduce a maximum displacement of the membrane by altering at least one of the following characteristics of the time-varying electric field: an amplitude; a frequency; a phase.

The controller may be operable to control the time-varying electric field generator to reduce a maximum displacement of the membrane by at least one of: decreasing the amplitude of the time-varying electric field; altering the frequency of the time-varying electric field to reduce or remove overlap between the frequency of the time-varying electric field and a mechanical oscillation frequency of the membrane; altering the phase of the time-varying electric field to be in counter-phase with a mechanical oscillation phase of the membrane, at least for the low modes.

Advantageously, altering the phase of the time-varying electric field to be in counter-phase with a mechanical oscillation phase of the membrane may enable mechanical oscillations of the membrane to be suppressed more quickly than other methods.

The controller may be operable to log the measured displacement and a time of measurement for each measurement of displacement as time-varying displacement data.

The controller may be operable to transform the time-varying displacement data to a frequency domain and extracting at least one mechanical oscillation frequency of the membrane. Transforming the time-varying displacement data to the frequency domain comprises using a fast Fourier transform.

The controller may be operable to control the time-varying electric field generator to alter at least one of the characteristics of the time-varying electric field to reduce the maximum displacement of the membrane by controlling the at least one characteristic of the time-varying electric field for a hold time during which the maximum displacement of the membrane returns to be within the predetermined displacement range and then reverting the at least one characteristic of the time-varying electric field to its value before the hold time.

The controller may be operable to control the time-varying electric field generator to alter at least one of the characteristics of the time-varying electric field to reduce the maximum displacement of the membrane by controlling the at least one characteristic of the time-varying electric field to reduce the maximum displacement of the membrane until the apparatus for removing particles from the membrane has finished removing particles from the membrane.

The time-varying electric field generator may comprise: at least one excitation electrode positioned proximate to a surface of the membrane when supported by the membrane support; and a mechanism for applying a time-varying voltage across the at least one excitation electrode to generate the time-varying electric field for inducing mechanical oscillations in the membrane when supported by the membrane support.

The at least one time-varying electric field generator may comprise: a first excitation electrode and a second excitation electrode, each electrode positionable proximate to different one of two opposed surfaces of the membrane when supported by the membrane support; and a mechanism for applying a time-varying voltage across the first excitation electrode and the second excitation electrode to generate the time-varying electric field for inducing mechanical oscillations in the membrane when supported by the membrane support.

The time-varying electric field generator may be configured such that there is a non-zero phase difference between the time-varying voltage applied to the first electrode and the time-varying voltage applied to the second electrode.

According to a third aspect of the invention, there is provided a method of cleaning a component for use in a lithographic apparatus comprising: cleaning the component in a cleaning module or a plurality of cleaning modules of an apparatus using: at least one removing mechanism for removing particles from the component and at least one preparing mechanism for reducing adhesion of the particles to the component, or a plurality of removing mechanisms for removing particles from the component.

The apparatus may comprise the plurality of cleaning modules. The method may further comprise sequentially passing the component through the cleaning modules to be cleaned.

The method may further comprise passing the component through a plurality of separation modules for removing the particles from the component, and/or passing the component through at least one preparation module for reducing adhesion of particles to the component and then passing the component through at least one separation module. Passing the component first through the preparation module means that, when removal of the particles from the component is carried out in the separation module, more particles may be removed than would have been possible (i.e. efficiency of the separation module for particle removal is significantly increased after treating the component in the preparation module).

The removing mechanism may comprise a vibration generating mechanism for generating mechanical oscillations in the component using a time-varying electric field. The method may further comprise: measuring a displacement of the component relative to the component at rest; determining if the measured displacement of the component is outside a predetermined range and controlling at least one characteristic of the time-varying electric field if the measured displacement of the component is outside the predetermined range.

According to a fourth aspect of the invention, there is provided a method of removing particles from a membrane, for use in a lithographic apparatus, comprising: inducing mechanical oscillations in the membrane using a time-varying electric field, to remove particles from the membrane; measuring a displacement of the membrane relative to the membrane at rest; determining if the measured displacement of the membrane is outside a predetermined range; and controlling at least one characteristic of the time-varying electric field if the measured displacement of the membrane is outside the predetermined range.

Advantageously, the method of removing particles from the membrane reduces the risk of run-away failure of the membrane. Advantageously, the method of removing particles from the membrane enables a field strength of the time-varying electric field generated by at least one electrode to be increased (e.g. to improve particle removal) without the risk of run-away failure of the membrane. Advantageously, the method of removing particles from the membrane enables the at least one electrode to be positioned closer to the membrane (e.g. to improve particle removal) without the risk of run-away failure of the membrane.

The membrane may comprise a pellicle.

The method may comprise measuring the displacement of the membrane substantially as frequently as a frequency of at least one of the following low mechanical oscillation eigenmodes of the membrane: mode 1 (e.g. lowest mode, monopole), mode 2 (e.g. dipole, long side), mode 3 (e.g. dipole, short side), mode 4 (e.g. quadrupole).

Advantageously, measuring the displacement of the membrane substantially as frequently as a frequency of at least one of the low frequency eigenmodes enables fewer displacement sensors (e.g. proximity sensors) to be used.

The method may comprise measuring the displacement of the membrane more frequently than at least one of: 1 Hz, 10 Hz, 100 Hz, 1000 Hz, 10,000 Hz.

The method may comprise measuring the displacement of the membrane less frequently than at least one of: 10 Hz, 100 Hz, 1000 Hz, 10,000 Hz.

The method may comprise measuring the displacement of the membrane more frequently than a frequency of at least one of the following low mechanical oscillation eigenmodes of the membrane: mode 1 (e.g. lowest mode, monopole), mode 2 (e.g. dipole, long side), mode 3 (e.g. dipole, short side), mode 4 (e.g. quadrupole).

Advantageously, measuring the displacement of the membrane more frequently than the low frequency eigenmodes enables better determination of at least one of an amplitude, frequency, phase of the mechanical oscillations of the membrane.

Measuring the displacement of the membrane relative to the membrane at rest may comprise measuring a displacement of at least a localized portion of the membrane relative to the localized portion of the membrane at rest.

The predetermined displacement range may comprise displacement of at least a localized portion of the membrane relative to the membrane at rest, with a smaller magnitude than at least one of: 10 μm, 100 μm, 1000 μm.

Determining if the measured displacement of the membrane is outside the predetermined range may be based on a measured maximum displacement of the membrane.

The characteristic of the time-varying electric field may comprise at least one of: an amplitude; a frequency; a phase.

Controlling the at least one characteristic of the time-varying electric field to reduce a maximum displacement of the membrane may comprise at least one of: decreasing the amplitude of the time-varying electric field; altering the frequency of the time-varying electric field to reduce or remove overlap between the frequency of the time-varying electric field and a mechanical oscillation frequency of the membrane; altering the phase of the time-varying electric field to be in counter-phase with a mechanical oscillation phase of the membrane.

Advantageously, altering the phase of the time-varying electric field to be in counter-phase with a mechanical oscillation phase of the membrane may enable mechanical oscillations of the membrane to be suppressed more quickly than other methods.

The method may comprise logging the measured displacement and a time of measurement for each measurement of displacement as time-varying displacement data.

The method may comprise transforming the time-varying displacement data to a frequency domain and extracting at least one mechanical oscillation frequency of the membrane. Transforming the time-varying displacement data to the frequency domain comprises using a fast Fourier transform.

Controlling the at least one characteristic of the time-varying electric field to reduce the maximum displacement of the membrane may comprise controlling the at least one characteristic of the time-varying electric field for a hold time during which the maximum displacement of the membrane returns to be within the predetermined displacement range and then reverting the at least one characteristic of the time-varying electric field to its value before the hold time.

Controlling the at least one characteristic of the time-varying electric field to reduce the maximum displacement of the membrane may comprise controlling the at least one characteristic of the time-varying electric field until the method of removing particles from the membrane has been completed.

Inducing mechanical oscillations in the membrane may comprise applying a time-varying voltage across at least one excitation electrode positioned proximate to a surface of the membrane.

The time-varying voltage may apply pressure pulses having a pressure of 10-1000 Pa, for example 100 Pa. The time-varying voltage may apply pressure pulses with a duration of 10-1000 ns, for example 100 ns. The time-varying voltage may have an average repetition rate of 10-1000 kHz, for example, 100 kHz. Advantageously, the time-varying voltage may have a variable peak pulse repetition rate of 1-10 MHz, to overlap a first/second/third harmonic frequency with a resonance of the relevant particle for optimal excitation.

The pressure pulses applied by the time-varying voltage may induce resonant oscillations of particles (i.e. masses) on the membrane (e.g. which acts as a spring) with an eigenfrequency of approximately 1-10 MHz. This eigenfrequency range corresponds to a maximum instantaneous acceleration a≅(2π)²A*vᵣₑₛ²˜10⁷ m/s² to a≅(2π)²A*vᵣₑₛ²˜10⁸ m/s² and a maximum instantaneous speed v≅(2π)*A*vᵣₑₛ≅1 to 10 m/s when an amplitude of the mechanical oscillations is A˜0.1 to 1 μm.

The pressure pulses and the time-varying voltage may have identical duration. The time-varying voltage (e.g. voltage pulses) are applied to electrodes having a cross-section S≅1 to 5000 mm² for example S=10 to 1000 mm². The electrodes may be positioned h≅0.1 to 10 mm away from the membrane. Advantageously, to provide a required electrostatic pressure

$$\\ ( P = \frac{1}{2} {ε}_{0} {E}^{{}_{} 2} ≅ 100 Pa ) ,$$

the electrode(s) may be positioned within 0.5 mm to 2.5 mm from the membrane.

Inducing mechanical oscillations in the membrane may comprise applying a time-varying voltage to each of a first excitation electrode and a second excitation electrode positioned proximate to opposed surfaces of the membrane.

Inducing mechanical oscillations in the membrane may comprise there being a non-zero phase difference between the time-varying voltage applied to the first excitation electrode and the time-varying voltage applied to the second excitation electrode.

According to a fifth aspect of the invention, there is provided a non-transitory computer readable storage medium comprising instructions which, when executed by processing circuitry, cause the processing circuitry to perform the membrane cleaning method.

Features mentioned above in accordance with any aspect of the present disclosure or below relating to any specific embodiment of the disclosure might be used, either alone or in combination with any other defined feature, in any other aspect or embodiment or to form a further aspect or embodiment of the disclosure.

### BRIEF DESCRIPTION OF THE DRAWINGS

Embodiments of the invention will now be described, by way of example only, with reference to the accompanying schematic drawings, in which:

FIG. 1 depicts a lithographic system comprising a lithographic apparatus, including a pellicle assembly, and a radiation source;

FIG. 2 depicts an apparatus for cleaning a pellicle with contamination according to an embodiment of the present invention;

FIG. 3 depicts an apparatus for cleaning a pellicle according to an embodiment of the present invention;

FIGS. 4a)-4d) depicts a pellicle and a VUV photon generating mechanism during steps of cleaning a pellicle according to an embodiment of the present invention;

FIG. 5a) depicts a pellicle and a VUV photon generating mechanism according to an embodiment of the present invention;

FIG. 5b) depicts a pellicle and a VUV photon generating mechanism according to an embodiment of the present invention;

FIG. 6 depicts a pellicle, a plasma generating mechanism, a heat generating mechanism and an electric field generating mechanism according to an embodiment of the present invention;

FIG. 7 depicts a pellicle and an electron beam generating mechanism according to an embodiment of the present invention;

FIG. 8 depicts a pellicle and a particle to be removed from the pellicle according to an embodiment of the present invention;

FIG. 9 shows an embodiment of a membrane cleaning apparatus according to the present invention, and a membrane;

FIG. 10 is a schematic view of part of the membrane shown in FIG. 9, showing a mechanism by which particles may be removed from the membrane using the membrane cleaning apparatus shown in FIG. 9 (with one cleaning part);

FIG. 11a shows a plot of an example voltage that may be applied across a membrane and an electrode as a function of time using the membrane cleaning apparatus shown in FIG. 9 (with one cleaning part);

FIG. 11b is a first schematic illustration of an excitation spectrum corresponding to an applied voltage of the form shown in FIG. 11a, showing excitation force applied to a membrane as a function of frequency of the excitation force, and schematically indicating a frequency composition of the pulsed voltage, and how this may be varied via modulation of a pulse repetition frequency;

FIG. 11c is a second schematic illustration of an excitation spectrum, schematically indicating a frequency composition of the pulsed voltage shown in FIG. 11a and how this may be varied via modulation of pulse repetition frequency and modulation of pulse shape;

FIG. 12 shows the embodiment of the membrane cleaning apparatus of FIG. 9 in use;

FIG. 13 shows a flow-chart describing a method of removing particles from a membrane, according to another embodiment of the present invention;

FIG. 14 shows a flow-chart describing a method of removing particles from a membrane, according to another embodiment of the present invention;

FIG. 15 shows a flow-chart describing a method of removing particles from a membrane, according to another embodiment of the present invention;

FIG. 16 shows a flow-chart describing a method of removing particles from a membrane, according to another embodiment of the present invention;

FIG. 17 shows an alternative embodiment of a membrane cleaning apparatus according to an embodiment of the present invention, and a membrane.

### DETAILED DESCRIPTION

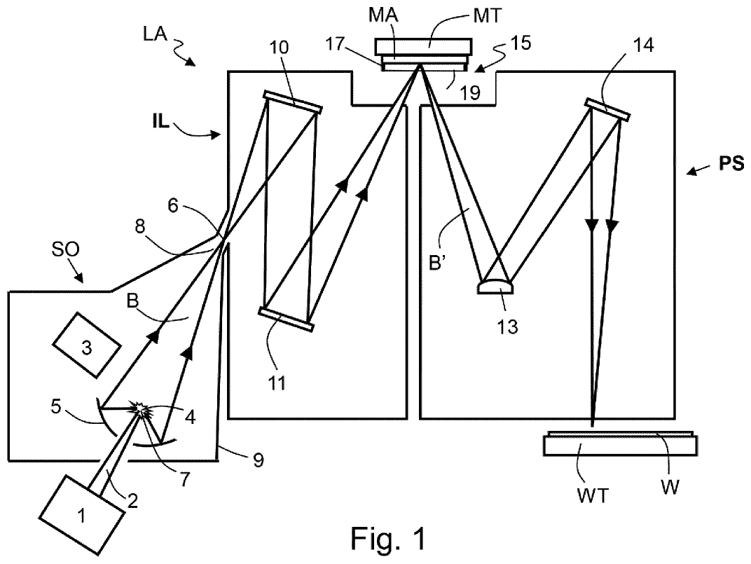

FIG. 1 shows a lithographic system comprising a radiation source SO and a lithographic apparatus LA. The radiation source SO is configured to generate an EUV radiation beam B and to supply the EUV radiation beam B to the lithographic apparatus LA. The lithographic apparatus LA comprises an illumination system IL, a support structure MT configured to support a patterning device MA (e.g., a mask), a projection system PS and a substrate table WT configured to support a substrate W.

The illumination system IL is configured to condition the EUV radiation beam B before the EUV radiation beam B is incident upon the patterning device MA. Thereto, the illumination system IL may include a facetted field mirror device 10 and a facetted pupil mirror device 11. The faceted field mirror device 10 and faceted pupil mirror device 11 together provide the EUV radiation beam B with a desired cross-sectional shape and a desired intensity distribution. The illumination system IL may include other mirrors or devices in addition to, or instead of, the faceted field mirror device 10 and faceted pupil mirror device 11. The radiation beam B passes from the illumination system IL and is incident upon the patterning device MA held by the support structure MT. The patterning device MA is protected by a pellicle 19, which is held in place by a pellicle frame 17. The pellicle 19 and the pellicle frame 17 together form a pellicle assembly 15.

After being thus conditioned, the EUV radiation beam B interacts with the patterning device MA. As a result of this interaction, a patterned EUV radiation beam B′ is generated. The projection system PS is configured to project the patterned EUV radiation beam B′ onto the substrate W. For that purpose, the projection system PS may comprise a plurality of mirrors 13,14 which are configured to project the patterned EUV radiation beam B′ onto the substrate W held by the substrate table WT. The projection system PS may apply a reduction factor to the patterned EUV radiation beam B′, thus forming an image with features that are smaller than corresponding features on the patterning device MA. For example, a reduction factor of 4 or 8 may be applied. Although the projection system PS is illustrated as having only two mirrors 13,14 in FIG. 1, the projection system PS may include a different number of mirrors (e.g., six or eight mirrors).

The substrate W may include previously formed patterns. Where this is the case, the lithographic apparatus LA aligns the image, formed by the patterned EUV radiation beam B′, with a pattern previously formed on the substrate W.

A relative vacuum, i.e. a small amount of gas (e.g. hydrogen) at a pressure well below atmospheric pressure, may be provided in the radiation source SO, in the illumination system IL, and/or in the projection system PS.

The radiation source SO shown in FIG. 1 is, for example, of a type which may be referred to as a laser produced plasma (LPP) source. A laser system 1, which may, for example, include a CO₂ laser, is arranged to deposit energy via a laser beam 2 into a fuel, such as tin (Sn) which is provided from, e.g., a fuel emitter 3. Although tin is referred to in the following description, any suitable fuel may be used. The fuel may, for example, be in liquid form, and may, for example, be a metal or alloy. The fuel emitter 3 may comprise a nozzle configured to direct tin, e.g. in the form of droplets, along a trajectory towards a plasma formation region 4. The laser beam 2 is incident upon the tin at the plasma formation region 4. The deposition of laser energy into the tin creates a tin plasma 7 at the plasma formation region 4. Radiation, including EUV radiation, is emitted from the plasma 7 during de-excitation and recombination of electrons with ions of the plasma.

The EUV radiation from the plasma is collected and focused by a collector 5. Collector 5 comprises, for example, a near-normal incidence radiation collector 5 (sometimes referred to more generally as a normal-incidence radiation collector). The collector 5 may have a multilayer mirror structure which is arranged to reflect EUV radiation (e.g., EUV radiation having a desired wavelength such as 13.5 nm). The collector 5 may have an ellipsoidal configuration, having two focal points. A first one of the focal points may be at the plasma formation region 4, and a second one of the focal points may be at an intermediate focus 6, as discussed below.

The laser system 1 may be spatially separated from the radiation source SO. Where this is the case, the laser beam 2 may be passed from the laser system 1 to the radiation source SO with the aid of a beam delivery system (not shown) comprising, for example, suitable directing mirrors and/or a beam expander, and/or other optics. The laser system 1, the radiation source SO and the beam delivery system may together be considered to be a radiation system.

Radiation that is reflected by the collector 5 forms the EUV radiation beam B. The EUV radiation beam B is focused at intermediate focus 6 to form an image at the intermediate focus 6 of the plasma present at the plasma formation region 4. The image at the intermediate focus 6 acts as a virtual radiation source for the illumination system IL. The radiation source SO is arranged such that the intermediate focus 6 is located at or near to an opening 8 in an enclosing structure 9 of the radiation source SO.

Although FIG. 1 depicts the radiation source SO as a laser produced plasma (LPP) source, any suitable source such as a discharge produced plasma (DPP) source or a free electron laser (FEL) may be used to generate EUV radiation.

As was described briefly above, the pellicle assembly 15 includes the pellicle 19 that is provided adjacent to the patterning device MA. The pellicle 19 is provided in the path of the radiation beam B such that radiation beam B passes through the pellicle 19 both as it approaches the patterning device MA from the illumination system IL and as it is reflected by the patterning device MA towards the projection system PS. This position of the pellicle 19 in the lithographic apparatus LA is an EUV radiation exposure position. The pellicle 19 comprises a thin film or membrane that is substantially transparent to EUV radiation (although it will absorb a small amount of EUV radiation). By EUV transparent pellicle or a film substantially transparent for EUV radiation herein is meant that the pellicle 19 is transmissive for at least 65% of the EUV radiation, preferably at least 80% and more preferably at least 90% of the EUV radiation. The pellicle 19 acts to protect the patterning device MA from particle contamination. The pellicle 19 may be herein referred to as an EUV transparent pellicle. The pellicle 19 may be made from any material which is sufficiently transparent for EUV radiation, such as Molybdenum Silicide (MoSi). MoSi is stronger than silicon at high temperatures because it cools more quickly than silicon. In other examples, the pellicle may be made from other materials, such as silicon, silicon nitride, graphene or graphene derivatives, carbon nanotube, or multilayer membranes formed by alternating EUV transparent materials.

Whilst efforts may be made to maintain a clean environment inside the lithographic apparatus LA, particles may still be present inside the lithographic apparatus LA. In the absence of the pellicle 19, particles may be deposited onto the patterning device MA. Particles on the patterning device MA may disadvantageously affect the pattern that is imparted to the radiation beam B and therefore the pattern that is transferred to the substrate W. The pellicle 19 provides a barrier between the patterning device MA and the environment in the lithographic apparatus LA in order to prevent particles from being deposited on the patterning device MA.

In use, the pellicle 19 is positioned at a distance from the patterning device MA that is sufficient such that any particles that are incident upon the surface of the pellicle 19 are not in the focal plane of the radiation beam B. This separation between the pellicle 19 and the patterning device MA, acts to reduce the extent to which any particles on the surface of the pellicle 19 impart a pattern to the radiation beam B. It will be appreciated that where a particle is present in the beam of radiation B, but at a position that is not in a focal plane of the beam of radiation B (i.e., not at the surface of the patterning device MA), then any image of the particle will not be in focus at the surface of the substrate W. In some examples, the separation between the pellicle 19 and the patterning device MA may, for example, be between 2 mm and 3 mm (e.g. around 2.5 mm). In some examples, a separation between the pellicle 19 and the patterning device may be adjustable.

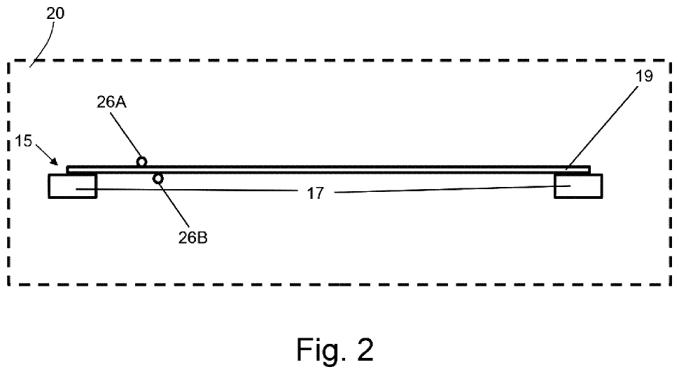

FIG. 2 is a schematic illustration of the pellicle assembly 15 in cross section and shows an apparatus 20 for cleaning the pellicle 19. The apparatus 20 is shown schematically as a dashed line and the features of the apparatus 20 will be described. A contamination particle 26A is schematically shown. The contamination particle 26A is shown on the pellicle 19 frontside (i.e. the side which would be facing away from the patterning device MA in use). In use, the pellicle 19 holds the contamination particle 26A sufficiently far from the patterned surface of the patterning device MA so that it is not imaged onto substrates by the lithographic apparatus LA.

In addition a contamination particle 26B is schematically shown on the pellicle 19 backside (i.e. the side which would be facing towards the patterning device MA in use). It is the contamination particle 26B (and any other contamination particles on the backside of the pellicle) which is of primary concern as it may cause defects and consequential productivity loss. That is, if the contamination particle 26B releases from the pellicle 19 and transfers from the pellicle 19 backside to the patterning device (reticle) MA frontside in the lithographic apparatus LA. However, the apparatus 20 may also be used to clean the contamination particles 26A from the pellicle 19 frontside.

Although the pellicle will be described as being cleaned by the apparatus, it will be appreciated that, in other embodiments, other components may be cleaned by the apparatus. For example, other components may comprise EUV transparent films, a dynamic gas lock membrane, or an EUV spectral purity filter.

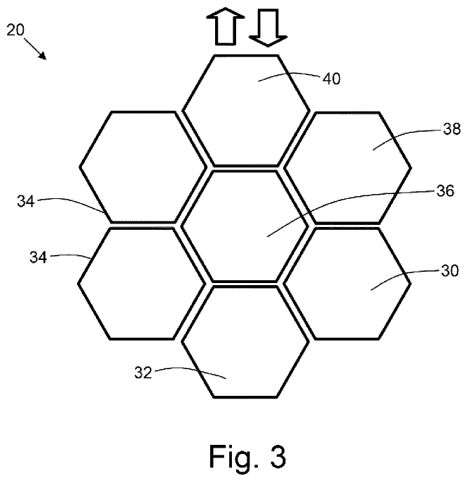

The apparatus 20 is shown (schematically) in more detail in FIG. 3. The apparatus 20 comprises a plurality of modules. These modules include cleaning modules and other modules for different purposes. The apparatus may be referred to as a pellicle cleaning cluster (i.e. having a cluster of modules). The cleaning modules comprise a preparation module 30 and a separation module 32. The separation module 32 is for removing particles 26A, 26B from the pellicle 19. Removing the particles 26A, 26B from the pellicle 19 may be considered to be a removing mechanism. The preparation module 30 is for reducing adhesion of the particles 26A, 26B to the pellicle 19 (e.g. before the pellicle 19 is moved to the separation module 32). The preparation module 30 may be considered to pre-treat the pellicle 19 to reduce the adhesion of the particles on it before the particles 26A, 26B are then removed (i.e. in the separation module 32). Reducing the adhesion of the particles 26A, 26B to the pellicle 19 may be considered to be a preparing mechanism. The removing mechanism and the preparing mechanism may be considered to be cleaning mechanisms. Cleaning a pellicle 19 may be considered to include both preparing for removing the particles 26A, 26B (i.e. reducing adhesion of the particles to the pellicle 19) and removing the particles 26A, 26B (from the pellicle 19).

There are also spare modules 34, which may be for one or more additional cleaning modules to be added to the apparatus 20. They may also be used for other modules as required. In other embodiments, there may be one or more than two spare modules. The apparatus 20 is configured such that one or more additional cleaning modules (or other modules) may be added to the apparatus 20. The modules are shown schematically as hexagons, but this is just an example to show that the modules may be connected to each other. It will be appreciated that the modules may be other shapes and sizes as required. In addition, there are six modules shown but it will be appreciated that there may be more or less than this number in the apparatus 20 as required. It will be appreciated that pellicles may be transferred between modules in a controlled environment, for example under vacuum, or atmosphere of user defined gas/pressure/temperature.

The other modules in the apparatus 20 may comprise a robot module 36 for moving the pellicle 19, (e.g. between cleaning modules), a pellicle library module 38 (more generally, a part library) comprising a plurality of pellicles which may be chosen to be cleaned and may be used in the lithographic apparatus LA, and a vacuum chamber module 40 for loading a reticle MA and pellicle 19 into the lithographic apparatus LA. The arrows adjacent to the vacuum chamber 40 show the direction of movement in and out of the apparatus 20. They may lead to the outside world (e.g. the cleanroom), i.e. not directly to the lithographic apparatus LA. The vacuum chamber module 40 is used to separate the vacuum inside the apparatus (i.e. in modules 30, 32, 34, 36, 38) from the outside world. The robot module 36 may be called an in vacuum robot (IVR). The reticle library module may be called an in vacuum library (IVL). The vacuum chamber module 40 may be called a (vacuum) load lock (LDLK). The modules of the apparatus 20 may be maintained under vacuum or under clean gas downflow so that (additional) particles 26A, 26B cannot go onto the pellicles 19. It will be appreciated that the other modules (i.e. modules robot module 36, pellicle library module 38, vacuum chamber module 40) are subservient/optional and may help to manipulate pellicles (or reticles), and they may also be separate from the apparatus 20.

In use, the pellicle 19 is inserted in the apparatus 20 and firstly is located in the preparation module 30, where the adhesion of the particles 26A, 26B may be reduced. This may be by different methods as will be explained. Following the adhesion reduction of the particles 26A, 26B to the pellicle 19, the pellicle 19 may be moved from the preparation module 30 to the separation module 32 by the robot module 36.

Vacuum may be maintained from the preparation module 30 to the separation module 32 so that the adhesion reduction is maintained and so that more particles 26A, 26B do not go onto the pellicle 19. In embodiments, the whole apparatus is maintained under vacuum (e.g. using the vacuum chamber module 40). In embodiments, the preparation module 30 and/or the separation module 32 may comprise a vacuum generating mechanism to produce a particular level of vacuum. The vacuum produced by the vacuum generating mechanism may at least assist in reducing adhesion of the particles to the component or removing the particles from the component.

In this embodiment, there is a single preparation module 30 and a single separation module 32. However, in other embodiments, there may a plurality of separation modules and/or a plurality of preparation modules. In embodiments, there may be no preparation module, i.e. there may be only one or more separation modules. Furthermore, in some embodiments, a preparation module and a separation module may be combined into a single module. This may still be considered to be a separation module as the particles are being removed from the pellicle, but the particles may also be subjected to adhesion reduction methods either during or before removing the particles. That is, the separation module 32 may be for reducing adhesion of particles to the component, either during or before removing the particles from the component. in this case, the separation module 32 includes a preparing mechanism and a removing mechanism.

In embodiments, at least one of the cleaning modules (e.g. the separation module 32) may comprise a plurality of cleaning mechanisms. In embodiments, the cleaning module (i.e. the separation module 32) may include a preparing mechanism and a removing mechanism. In embodiments, the preparing mechanism and the removing mechanism may be the same mechanism, i.e. a single mechanism may perform both functions. In embodiments, the cleaning module (i.e. the separation module 32) may include a plurality of removing mechanisms. If there are more than one cleaning module, then all of the cleaning modules together may comprise a plurality of cleaning mechanisms, i.e. one cleaning module may comprise one cleaning mechanism and another cleaning module may comprise another cleaning mechanism. One or more of the cleaning modules may each comprise a plurality of cleaning mechanisms.

Methods of reducing the adhesion of the particles to the pellicle 19 (i.e. preparing mechanisms) will now be described. The preparation module 30 may comprise a heat generating mechanism configured to generate heat to dry the pellicle 19 and/or the particles 26A, 26B in a vacuum environment. The water vapor pressure in the preparation module 30 and in the separation module 32 may have a pressure below 1E-6 mBar (1E-4 Pa), preferably below 1E-7 mBar (1E-5 Pa), more preferably below 1E-8 or 1E-9 mBar (1E-6 Pa or (1E-7 Pa), even more preferably below 1E-10 mBar (1E-8 Pa).

The heat generating mechanism may be a radiative heater, e.g. a laser or an IR lamp. The radiative heater may be configured to have an average power density in a range of 1-5 W/cm² at the film of the pellicle 19 applied for a range of 0.1-1000 seconds or 10-1000 seconds. Preferably, the radiative heat towards pellicle border is limited to below 1 W/cm² and/or the border is in contact with a heat sink such that pellicle border temperature remains below 400 C, preferably below 200 C. This may avoid pellicle rupture due to CTE (thermal expansion coefficient) difference between pellicle film and pellicle border.

Vacuum and heat lead to the removal of a capillary water layer (or even nano-droplets) present in the contact region between particle 26A, 26B and pellicle 19. Pellicle 19 may have a hydrophilic surface (for example, SiO₂); particles 26A, 26B left on pellicles 19 at production may be hydrophilic or super-hydrophilic, which in turn imposes a specification of 200-500 C temperature which may be needed to remove water collected on particles and at the contact spot particle/pellicle. Baking pellicles out is important in order to suppress adhesion contribution by capillary forces. The pellicles 19 may be heated up to 500° C., which is a design temperature for the pellicle in the EUV lithographic apparatus LA in operation. Thus radiative baking out is acceptable for the pellicles 19. The partial pressure may also be maintained at extremely low levels (e.g. <<1E-9 mbar) in order to ensure that a new film of water does not form immediately after ‘drying’.

As an alternative to heating using a radiative heater, a plasma may be used. That is, the preparation module 30 may comprise a plasma generating mechanism for generating a plasma adjacent to or around the pellicle 19. In this case, ions, radicals and excited species of the plasma may promote water outgassing, including water trapped in and around the particles 26A, 26B. The plasma preferably comprises a noble gas and/or hydrogen (H₂) in order to prevent loss of optical or mechanical properties of the pellicles 19 during the treatment (for example, expected by oxidation).

Thus, the preparation module 30 may comprise a mechanism (e.g. the heat generating mechanism and/or the plasma generating mechanism) to remove water from between particles 26A, 26B and the pellicle 19. This removal of water may reduce the adhesion of the particles 26A, 26B to the pellicle 19. This means that, when removal of the particles 26A, 26B from the pellicle 19 is carried out (e.g. in the separation module 32), more particles 26A, 26B may be removed (i.e. efficiency of separation module 32 for particle removal is significantly increased after treating pellicles in the preparation module 30).

In addition, or alternatively, the plasma generating mechanism may reduce adhesion of the particles 26A, 26B to the pellicle 19 through another means. In some embodiments, the effect of the plasma generating mechanism on the composition or roughness of the particles 26A, 26B and/or pellicle itself can lead to significant reduction of adhesion either be increasing effective separation between particle 26A, 26B and pellicle 19 or by changing Hamaker constant.

In the lithographic apparatus LA, EUV photons, EUV plasma and/or photo electrons promote oxidation and/or reduction of surfaces (may be material specific), break chemical bonds and lead to etching for instance via the formation of volatile hydrides or oxides. These processes can change the chemical interaction between particle and pellicle, but can also locally change the shape (roughness) of the particle, which leads to a reduced contact surface and therefore reduced adhesion. Similar effects may be expected in case of plasma or electron beam in combination with a reactive gas acting on a pellicle or a particle.

The EUV photons furthermore lead the release of electrons from the pellicle which have similar effects as the photons themselves.

Reactive hydrogen species as present in the plasma around the pellicle may etch organic and other materials, induce other chemical reactions and may lead to crystalline hydride formation. This change in morphology may reduce adhesion by reducing contact area due to surface roughening. It is believed that applying similar stress to the pellicle and particles prior to the separation tool treatment may improve cleaning efficiency.

As mentioned, one way of emulating the reduced adhesion effect of the particles 26A, 26B to the pellicle 19 in the apparatus 20 may be using the plasma generating mechanism. The plasma generating mechanism may be configured to generate a plasma with either hydrogen or hydrogen and water. In the case with the water, the water content may be at least 1000 times smaller than the hydrogen content to maintain pellicle 19 properties (i.e. not damage the pellicle 19). Power dissipation to the pellicle 19 preferably is in a range 1 mW/cm²-1 W/cm².

Another way of emulating the reduced adhesion effect in the apparatus 20 may be using an electron beam generating mechanism. That is, in embodiments, the preparation module 30 comprises an electron beam generating mechanism for generating an electron beam to be incident on the pellicle 19. The electron beam generating mechanism may be configured to generate the electron beam in an environment with hydrogen or hydrogen and water, and/or noble gas with pressure in the range 0.001 Pa to 100 Pa, preferably 0.1 Pa to 10 Pa. Preferably, treatment by an electron beam follows pellicle baking out and/or plasma treatment, when water layer surrounding the particles (and shielding it from the electrons) has been removed.

The environment may have a pressure in a range of 1E-4 mBar (0.01 Pa) to 1E-1 mBar (10 Pa). The electron beam generating mechanism may be configured to have an energy in a range of 30-3000 eV and/or the current density at the pellicle 19 may be in a range 10 uA/cm² to 10 mA/cm², while power dissipation (beam energy times beam current density) stays below 1 W/cm². This is so the pellicle is not damaged. The electron beam should at least irradiate the backside of the pellicle 19 (with particles 26B) and optionally may irradiate the frontside (at the same time, using additional source) or sequentially using the single source and changing mutual orientation of source and the pellicle. The pellicle should be grounded at least for the duration of the electron beam treatment to drain the current deposited onto the pellicle by the beam.

Another way of emulating the reduced adhesion effect in the apparatus 20 may be using a VUV photon generating mechanism (i.e. exposure to VUV photons). That is, in embodiments, the preparation module 30 comprises a VUV photon generating mechanism (i.e. a VUV photon source) for providing VUV photons to be incident on the pellicle 19, preferably at least at the backside, containing critical particles 26B. The VUV photon generating mechanism may provide radiation to the pellicle in a reactive environment, for example hydrogen or hydrogen and water vapor. Power dissipation to the pellicle from VUV photons absorption preferably is below 1 W/cm².

Alternatively, the reduced adhesion effect in the apparatus 20 may be emulated using EUV photons. That is, in embodiments, the preparation module 30 comprises an EUV photon generating mechanism (i.e. a EUV photon source) for providing EUV photons to be incident on the pellicle 19, preferably at least at the backside, containing critical particles 26B. The EUV photon generating mechanism may provide radiation to the pellicle in a reactive environment, for example hydrogen or hydrogen and water vapor. Power dissipation to the pellicle 19 from EUV photons absorption preferably is below 1 W/cm². However, it may be less expensive to use VUV photons than EUV photons.

Although hydrogen or hydrogen and water vapor are mentioned as being used for the plasma or environment for the electron beam, VUV or EUV photons. It will be appreciated that, in other embodiments, other reducing/oxidizing agents than H₂ or H₂O may be used. However, the ratio between the reducing/oxidizing agents should be controlled to ensure pellicle mechanical properties (strength, tension) and optical properties (transmission/reflection) are maintained during the adhesion removal step. That is, the reducing agent concentration may be relatively much higher than the oxidizing agent concentration. This may be to ensure that the mechanical properties (strength and tension) and optical properties (transmission and reflection) of the pellicle 19 are maintained. As an example, the reducing agent concentration may be 1000 times or more higher than the concentration of the oxidizing agent.

In embodiments, the preparation module 30 may comprise a radical generating mechanism for generating H* (atomic hydrogen) adjacent to or around the pellicle 19. The radical generating mechanism may comprise the plasma generating mechanism and/or a hot filament, suspended in the hydrogen flow.

It will be appreciated that each of the different methods for reducing adhesion of the particles 26A, 26B to the pellicle 19 may be carried out in separate preparation modules 30 which may be included in the plurality of cleaning modules of the apparatus 20. For example, one preparation module may comprise the heat generating mechanism and another, separate, preparation module may comprise the electron beam generating mechanism. It will also be appreciated that, in some embodiments, there may be more than one of the different methods for reducing adhesion of the particles in the same preparation module.

Some methods of removing the particles 26A, 26B from the pellicle 19 (i.e. removing mechanisms) will now be described. The methods and apparatus as depicted in either of published patent applications WO2021073799, and WO2020109152 (which are herein incorporated in their entirety by reference) may be used as an option in or for the separation module 30. The separation module 30 may comprise a VUV photon generating mechanism for generating VUV photons to be incident on the component.

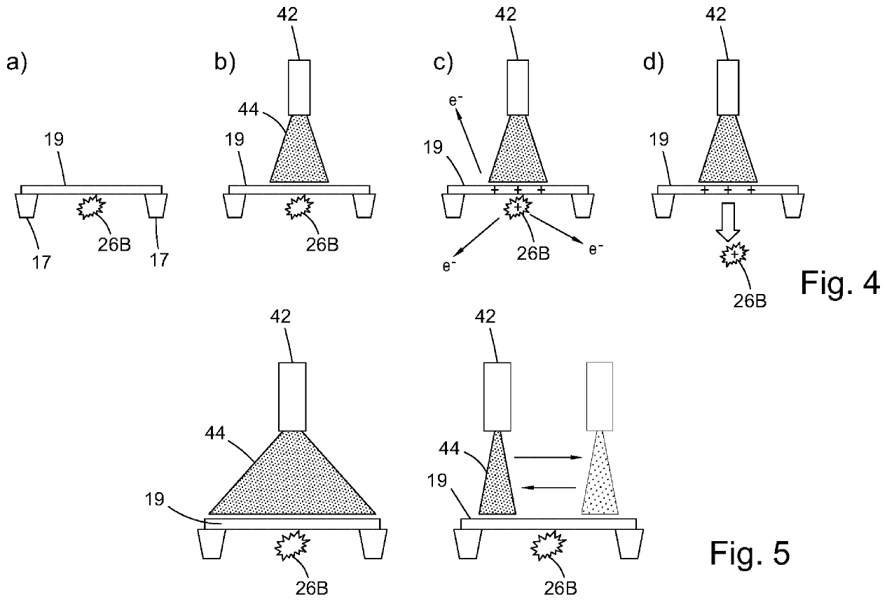

FIG. 4a) shows the particle 26B on pellicle 19 backside (i.e. the reticle side of the pellicle 19) with the pellicle 19 being supported by the pellicle frame 17. FIG. 4b) shows a VUV photon generating mechanism 42 generating VUV light (VUV photon beam 44) onto the pellicle 19. The VUV light illuminates the area of the pellicle 19 where the particle 26B is located. The VUV light may have wavelengths in the range 20-200 nm (62 eV-6.2 eV). Vacuum Ultra Violet (VUV) light sources may be more readily available than EUV sources from multiple suppliers and they may be less expensive. In general, EUV light is not easily obtained in sufficient dose for pellicle cleaning.

As shown in FIG. 4c), the VUV photons charge the particle 26B and the pellicle 19 using the photo-electric effect. The pellicle 19 and the particle 26B are both positively charged due to electrons (e−) being ejected. Since both the pellicle 19 and the particle 26B have the same charge, there is thus an electrostatic repulsive force between the particle 26B and the pellicle 19.

As shown in FIG. 4d), electrostatic repulsion between the particle 26B and the pellicle 19 (e.g. dielectric surface) ejects the particle 26B from the pellicle 19. This is assuming the electrostatic repulsive force between the particle 26B and the pellicle 19 is larger than the adhesion force holding the particle 26B on the pellicle 19. The adhesion of the particle 26B to the pellicle 19 may have been reduced in the preparation module 30 previously.

In this embodiment, the VUV photon beam 44 (i.e. VUV photons) is incident on the opposite surface to be cleaned of the pellicle 19 (i.e. in this embodiment, it is the frontside of the pellicle 19 that the light is incident on). That is, VUV light is shone through the pellicle 19). The VUV light being incident on the surface of the pellicle 19 opposite to the surface to be cleaned may lead to increased ionization between the particle 26B and the pellicle 19, thus maximizing the repulsion and cleaning effect. In other embodiments, the VUV light may be incident on the surface of the pellicle 19 to be cleaned (e.g. the backside of the pellicle 19). The side of the pellicle that the VUV light is incident on may depend on the chosen light source wavelength and the material of the pellicle 19. The backside of the reticle may be typically the side of the pellicle 19 to be cleaned (or at least is more important to be cleaned) but the frontside of the reticle may also be cleaned.

This method can then be applied over the entire surface of the pellicle 19 surface, irrespective of the particle 26B location. Thus, the technique does not require accurate metrology to guide it and can remove particles 26B of very small size as it is not limited by the detection limit of metrology tools.

Previous systems for cleaning the pellicle may have low throughput as they only clean spots (i.e. they clean the pellicles very locally). They require information on the locations of the particles to be removed and will then remove these individual particles. This makes these techniques rather slow and dependent on accurate metrology to give locations of all particles that are a potential reticle contamination risk.

FIG. 5a) shows an embodiment of the VUV photon generating mechanism 42 generating the VUV photon beam 44 to illuminate (substantially) the full area of the surface of the pellicle 19 at the same time. Thus, all particles 26B on the pellicle 19 will be charged by the VUV photons at once (at the same time), and thus may be removed from the pellicle 19 in a relatively quick timescale (i.e. much quicker than locating a particle first using metrology and then removing the particle that was found).

FIG. 5b) shows an embodiment of the VUV photon generating mechanism 42 generating the VUV photon beam 44 to illuminate part of the surface of the pellicle 19 and then scanning the VUV photon beam 44 across the surface of the pellicle 19 so that the whole surface of the pellicle 19 is illuminated (albeit not at the same time). The VUV photon generating mechanism 42 may be configured to scan the VUV photon beam 44 (i.e. the VUV photon beam 44 is scannable). Thus, all particles 26B on the pellicle 19 will be charged by the VUV photons in a relatively short timescale (the time is takes to scan the beam across the whole surface), and thus may be removed from the pellicle 19 in a relatively quick timescale (i.e. this is still much quicker than locating a particle first using metrology and then removing the particle that was found).

In some embodiments, the separation module 32 may comprise a plasma generating mechanism.

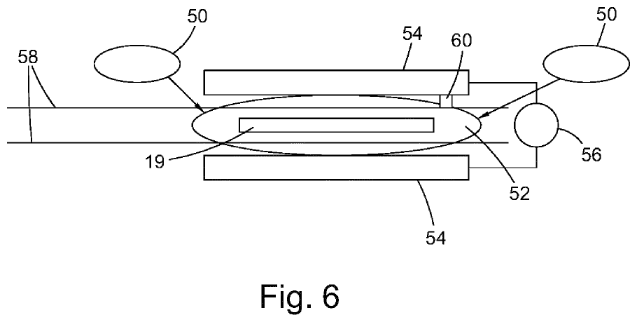

FIG. 6 shows a plasma generating mechanism (plasma source) 50 for generating a plasma 52 adjacent to or around the pellicle 19. In this embodiment, there are two plasma sources 50 but, in other embodiments, there may only be one plasma source. The plasma 52 charges the particles 26A, 26B (not shown). The gas flow (together with the plasma) may give a ‘kick’ to the particles 26A, 26B. This kick may, by itself, knock out some of the particles 26A, 26B.

In addition, the separation module 30 comprises an electric field generating mechanism for transporting the particles 26A, 26B away from the pellicle 19. The electric field generating mechanism comprises two collector electrodes 54, one located on each side of the pellicle 19. There is a AC/DC voltage supply 56 provided to supply voltage to the two collector electrodes 54. This sets up an electric field across the pellicle 19. Thus, the charged electrodes 54 attract the charged particles 26A, 26B. The particles 26A, 26B may all be positively charged. More generally, there may be provided a mechanism for applying a voltage across the pellicle 19 and the collector electrode 54.

Thus, the particles 26A, 26B are charged by the plasma 52 and then attracted to the collector electrodes 54. In this way, the particles 26A, 26B are removed from the pellicle 19.

The collector electrodes 54 may be in the form of plates covering substantially all of the pellicle 19. This makes it an area cleaning method (i.e. the full area of the surface of the pellicle 19 may be cleaned at the same time using this method). The plates may be metal plates. The plates may be flat. In another embodiment, the collector electrodes 54 may comprise a grid of electrodes.

The particles 26A, 26B may remain stuck to the collector electrodes 54 when the power to the voltage supply 56 is on. Thus, the pellicle 19 may be removed with the particles 26A, 26B stuck to the collector electrodes 54. This may be so that the particles 26A, 26B cannot return to the pellicle 19 when the power to the collector electrodes 54 is turned off.

There may also be provided two retractable shields 58 configured to prevent particles 26A, 26B from returning to the pellicle 19 when the power supply to the collector electrodes 54 is turned off. The shields 58 may be moved into place between the electrodes 54 and the pellicle 19 when it is desired to turn off the voltage supply 56. Once the power is off, the particles 19 may be free to move away from the electrode 54 but cannot return to the pellicle 19 again as the shields 58 are in the way. If it is desired to turn the power back on so that the cleaning process is started again, the shields 58 may be retracted so that particles 26A, 26B can reach the collector electrodes 54. In addition, the shields 58 may be retracted so that the particles may be cleaned off the shields 58, e.g. at regular intervals. In some embodiments, there may be only one shield 58 (e.g. if there is only a single collector electrode 54).

In some embodiments, if required, a heat generating mechanism (a heating source) 60 can also be employed to induce particle transfer from pellicle 19 to the collector electrode 54. The heat generating mechanism 60 may heat the pellicle 19 and induce particle transfer. The heat generating mechanism 60 may be a laser.

In embodiments, a frequency sweep may be used to couple to the particles. In other embodiments, an impulse/white noise electrical signal may be used to couple to the particles.

This method has an advantage of cleaning the whole surface of the pellicle 19 at the same time. It may more effectively clean the pellicle 19 (i.e. remove more particles and/or do so in a quicker time). It may be quicker to clean the whole pellicle 19 than other methods which may only have used localised cleaning or required prior location information of defects. Other previous systems made holes in the pellicle during cleaning which leads to loss of strength and breakage of films.

The separation module 32 may comprise a vibration generating mechanism for generating mechanical oscillations in the pellicle 19. Further detail may be found in WO2020109152 (which is herein incorporated in its entirety by reference).

The vibration generating mechanism may comprise an excitation electrode; and a mechanism for applying a time-varying voltage across the excitation electrode and the pellicle 19. In other embodiments, there may be a plurality (e.g. two) of excitation electrodes. The vibration generating mechanism for inducing mechanical oscillations in the pellicle 19 may also induce mechanical oscillations in particles 26A, 26B situated on the pellicle 19. This oscillation of such particles 26A, 26B situated on the pellicle 19 may be sufficiently large to remove particles from the pellicle 19.

The separation module 32 may comprise an electric field generating mechanism for transporting particles away from the pellicle 19. The electric field generating mechanism may comprise a collector electrode; and a mechanism for applying a voltage across the pellicle 19 and the collector electrode. In embodiments, the excitation electrode and collector electrode may be the same part.

Any particles 26A, 26B which are removed by the vibration generating mechanism for inducing mechanical oscillations are mainly transported away from the pellicle 19 by the inertia, since particles launched from vibrating pellicle keep their momentum (corresponds to the speed of 0.1-10 m/s).

Previous systems for removing particles from the pellicle before the pellicle is put into the lithographic apparatus may be shown to be less effective at releasing particles from the pellicle than the lithographic apparatus LA. The lithographic apparatus LA has multiple stressors (i.e. cleaning mechanisms) that work on the particle release. Vibrations are of particular importance. In addition, it has many aspects that may contribute to the release of particles via a reduction in adhesion, such as photons, electrons, plasma, radicals and heat. Many different physical effects may contribute to the reduction in adhesion force in a lithographic apparatus LA. This comprises, but is not limited to, EUV photons, electrons, vacuum, plasma, radicals and heat.

A previous system for removing particles may remove particles via vibrations (albeit induced differently than in the lithographic apparatus LA). However, these previous systems do not include most of the other adhesion reducing actors. This leads to a reduced release and insufficient cleaning performance.

The apparatus 20 comprising a plurality of modules may be used to mimic and surpass the release of particles in an EUV lithographic apparatus LA. The apparatus 20 may remove most or all of the particles that would be released in the lithographic apparatus LA. This has an advantage of reduced cost and increased productivity as pellicle cleaning may be carried out to the required standard using the separate apparatus 20.

The apparatus 20 has an advantage over other, single-stage, cleaner concepts in that it encompasses a plurality of the stressors (e.g. one stressor in each cleaning module) that occur in the lithographic apparatus LA. Therefore, it is able to clean (i.e. remove) any particle that may cause a problem in the lithographic apparatus LA. The stressors may be considered to correspond to cleaning mechanisms or adhesion reducing mechanisms.

Single actuator cleaners only mimic a maximum of one effect in the lithographic apparatus LA. This can be effective for some particles, but not for all. It is not possible to ab-initio know the composition of particles on the pellicle. The pellicle may contain particles of different material. These may also change in the future due to wanted and unwanted changes in the process flow or factory-conditions. Therefore it is desired that a pellicle cleaner should not only work for current particles, but should also be robust for any future particles. To accomplish this, the apparatus 20 may mimic some or all of the processes as they occur in the lithographic apparatus LA.

The apparatus 20 offers the same stressors as the lithographic apparatus LA, but at a much lower cost, because all the imaging etc. features of the lithographic apparatus LA are not included. In addition, the apparatus 20 includes a boost factor compared with the stressors in the lithographic apparatus LA (e.g. vibrations in the separation module 32 to remove the particles may be about 100-1000× more intense than in lithographic apparatus LA). There can also be a boost in other stressors in the apparatus 20 when compared to the lithographic apparatus LA, e.g. in heat, reactive ions or radical dose or energetic electrons dose.

Some previous cleaning tools are based on inertial forces (e.g. via vibrations), which are effective for relatively heavy, large particles but less effective for relatively light, small particles. Some pellicles shed particles due to the same inertial forces in the lithographic apparatus LA. However, a cleaning tool based on inertial forces may be less efficient for other pellicles, because particles may be released from these pellicles by e.g. electric forces in the lithographic apparatus LA. Therefore, the cleaning tool based on inertial forces may clean different particles from the pellicles than those that may cause defectivity issues in the lithographic apparatus LA.

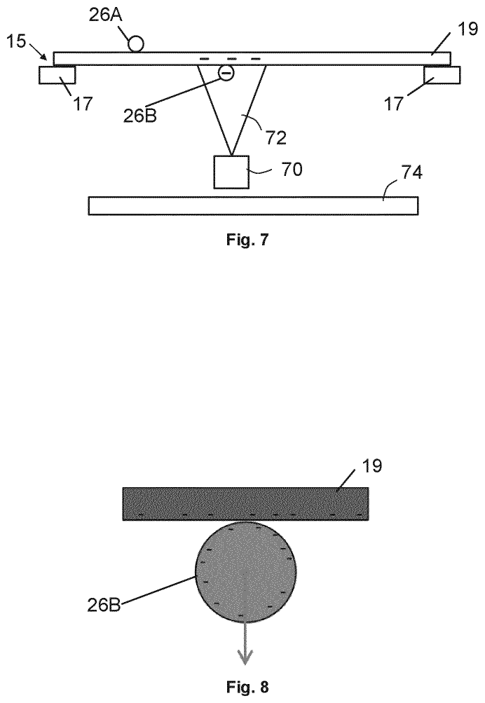

FIG. 7 shows an electron beam generating mechanism 70 for generating an electron beam 72 to be incident on the backside of the pellicle 19 (i.e. in this embodiment, the side having the particles 26B to be removed). It will be appreciated that, in other embodiments, the electron beam 72 may be incident on the frontside of the pellicle 19 in order to clean the particles 26A on the frontside of the pellicle 19. In this embodiment, the electron beam generating mechanism 70 is a removing mechanism (i.e. for removing particles from the pellicle), rather than, as previously described, a preparing mechanism (i.e. for reducing adhesion of the particles to the pellicle). It will be appreciated that, in some embodiments, the electron beam generating mechanism may be both a preparing mechanism and a removing mechanism.

The electron beam 72 illuminates the area of the pellicle 19 where the particle 26B is located. The electron beam 72 will electrically (negatively) charge the pellicle 19 and the particle 26B on it. The pellicle 19 and the particle 26B being both negatively charged (i.e. having the same charge) means that there is thus an electrostatic repulsive force between the particle 26B and the pellicle 19. This repelling force between the particle 26B and the pellicle 19 may result in the removal of the particle 26B from the pellicle 19, thus cleaning the pellicle 19.

FIG. 8 illustrates the distribution of negative charge on the particle 26B and the pellicle 19 in more detail. The direction of the electric force is shown by the arrow (i.e. perpendicularly away from the pellicle 19). The pellicle 19 may have a dielectric top layer on the pellicle 19 backside (i.e. the particle 26B may be in contact with this dielectric layer). In this situation, the electric force is particularly efficient as the dielectric layer can accumulate high charges, leading to a large electric release force. The pellicle 19 may also have a dielectric top layer on the pellicle 19 frontside, i.e. may have dielectric surfaces on both backside and frontside of the pellicle 19.

For highest cleaning efficiency, the electron beam 72 should be high-energetic: preferably above 80 eV. The higher the energy, the better the cleaning. The electron beam 72 may be pulsed. Pulsed exposure modes may be advantageous, as they may lead to high transient forces. The electron beam may be applied simultaneously with plasma. This is advantageous at least for pellicle that is floating, as it allows to prevent build up of floating potential and eventual repulsion of electrons from the electron beam. The plasma may be generated from the plasma generating mechanism.

The cleaning (i.e. removal of particles 26B) may be carried out by targeting particles 26B that were identified by inspections. Alternatively, the cleaning may be on the pellicle 19 as a whole. The latter option has the advantage that it does not rely on metrology. Cleaning a whole pellicle 19 could be either with a relatively large electron beam spot that covers substantially the entire pellicle 19, or by scanning a smaller electron beam spot across the pellicle 19. This scanning may be by deflection coils, as is done in e.g. an SEM (Scanning electron microscope) or a CRT (cathode-ray tube) monitor.

In embodiments, the electron beam generating mechanism may comprise a scanning electron microscope (SEM). This provides an advantage of in-situ imaging of the particles 26B and/or the pellicle 19 and evaluating the cleaning. This may lead to more time-efficient cleaning. However, it will be appreciated that, for removing the particles 26B from the pellicle 19, imaging is not necessary and only an electron beam is required. This may be by using an electron gun.

Particles 26B repelled from pellicle 19 may generally not return to the pellicle 19, e.g. they may land on walls of the vacuum chamber around the pellicle 19 or be flushed with the flow. However, in embodiments, the removed particles 26B may be collected by an optional electrode 74 (e.g. any metal object). The electrode 74 may be considered to be a collector electrode. The electrode 74 may attract the released particle 26B, because the particles 26B are negatively charged. The attraction works if there is a positive voltage on the electrode 74, but also if it is grounded. In the latter case there is a mirror force that attracts the (negatively) charged particle 26B. The electrode 74 may be covered by a (thin) dielectric to prevent the particle 26B from losing its charge to it. Collecting the particles 26B has the advantage that they will not redeposit on the pellicle 19. Additionally, the electrode 74 may enhance the electric cleaning force-see above with respect to the electric field generating mechanism for transporting the particles 26B away from the pellicle 19.

Embodiments of the present invention relate to apparatus and associated methods for removing particles from a membrane using an electric field. In particular, some embodiments of the present invention are particularly well suited and adapted to cleaning relatively thin membranes (such as, for example, pellicle membranes), which are fragile.

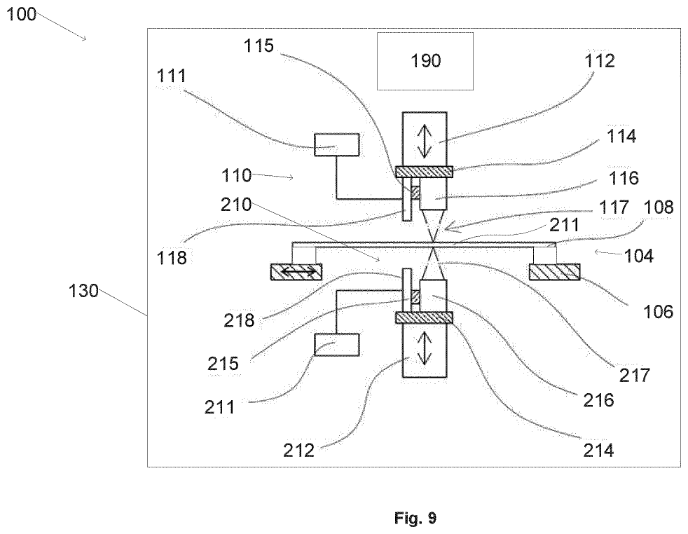

Some embodiments of the present invention exploit the fact that relatively thin membranes (such as, for example, pellicle membranes) are relatively flexible, by inducing mechanical oscillations in the membrane. In turn, this will also induce mechanical oscillations of the particles situated on the membrane. This oscillation of such particles situated on the membrane may be sufficiently large to remove particles from the membrane. In turn, any such particles which are removed by the mechanism for inducing mechanical oscillations may be transported away from membrane using their own momentum. Examples of such embodiments are now described with reference to FIGS. 9 to 16. It will be appreciated that, in embodiments, components other than a (pellicle) membrane may be cleaned using these mechanical oscillations.

A membrane cleaning apparatus 100 according to a first embodiment of the invention is now described with reference to FIGS. 9-12.

FIG. 9 shows a cross-section through the membrane cleaning apparatus 100, which comprises: a moveable stage 106, a first cleaning part 110, a second cleaning part 210, a vacuum chamber 130, and a controller 190.

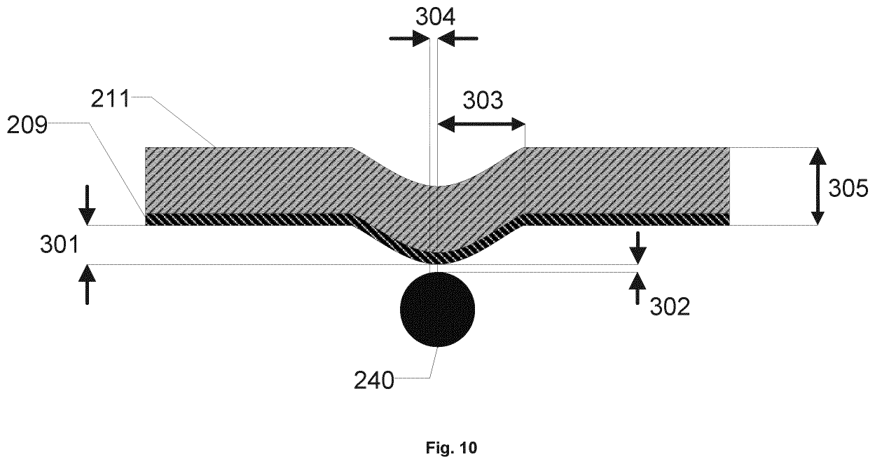

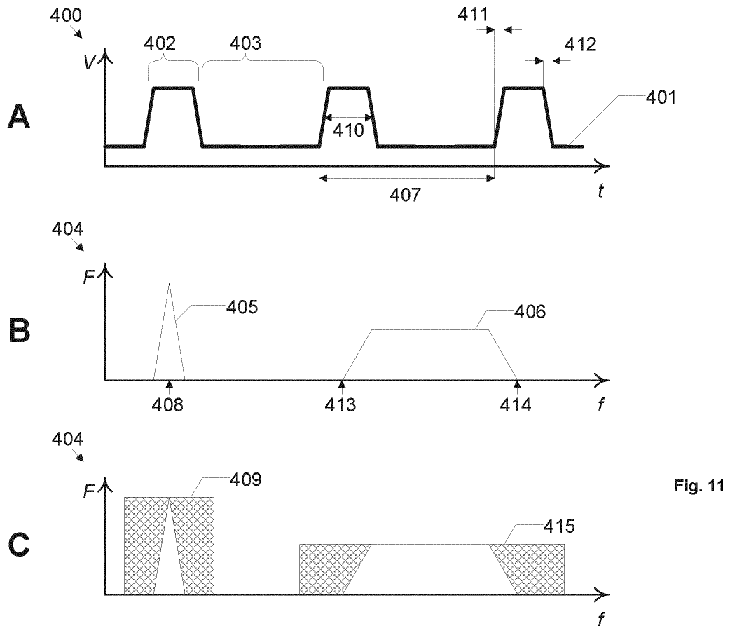

Also shown in FIG. 9 is a membrane assembly 104. The membrane assembly 104 comprises a membrane 211 and membrane support in the form of a conducting frame 108. The conducting frame 108 is a generally rectangular frame. The conducting frame 108 and one or more surfaces of the membrane 211 are coated in a conducting (e.g. a metallic) coating 209 (see FIG. 10) so that this conducting coating 209 is in electrical contact with the conducting frame 108. Alternatively, the pellicle film itself may comprise a conducting material, and extends to the pellicle frame.

The first cleaning part 110 comprises: a first voltage source 111, a first actuator 112, a first connector 114, a first isolator 115, a displacement sensor in the form of a first proximity sensor 116, and a time-varying electric field generator in the form of a first electrode 118.

The second cleaning part 210 comprises: a second voltage source 211, a second actuator 212, a second connector 214, a second isolator 215, a displacement sensor in the form of a second proximity sensor 216, and a time-varying electric field generator in the form of a second electrode 218.

The moveable stage 106, the membrane assembly 104, the first cleaning part 110, and the second cleaning part 210, are disposed within the vacuum chamber 130.

The conducting frame 108 comprises a central rectangular aperture. A lower surface of an outer portion of the membrane 211 is fixed to an upper surface of the conducting frame 108. An inner portion of the membrane 211 is suspended above the moveable stage 106 within the central rectangular aperture of the conducting frame 108. The conducting frame 108 of the membrane assembly 104 has a lower surface that is supported by an upper surface of the moveable stage 106. The first electrode 118 is in the form of a combined excitation/collector electrode. The second electrode 218 is in the form of a combined excitation/collector electrode.

The membrane assembly 104 is positioned between the first cleaning part 110 and the second cleaning part 210. The first cleaning part 110 is positioned above the membrane 211 and the second cleaning part 210 is positioned below the membrane 211. The first cleaning part 110 is configured to be opposing the second cleaning part 210.

A lower surface of the first actuator 112 is connected to an upper surface of the first connector 114. A lower surface of the first connector 114 is connected to an upper surface of the first proximity sensor 116. The lower surface of the first connector 114 is connected to an upper surface of the first electrode 118. The first isolator 115 is positioned between the first proximity sensor 116 and the first electrode 118. The first voltage source 111 is electrically connected to the first electrode 118 at one end and to a ground (e.g. to the vacuum chamber 130) at the other end (not shown for clarity). A lower surface of the first proximity sensor 116 and a lower surface of the first electrode 118 are facing an upper surface of the membrane 211.

An upper surface of the second actuator 212 is connected to a lower surface of the second connector 214. An upper surface of the second connector 214 is connected to a lower surface of the second proximity sensor 216. The upper surface of the second connector 214 is connected to a lower surface of the second electrode 218. The second isolator 215 is positioned between the second proximity sensor 216 and the second electrode 218. The second voltage source 211 is electrically connected to the second electrode 218 at one end and to the ground (e.g. to the vacuum chamber 130) at the other end (not shown for clarity). An upper surface of the second proximity sensor 216 and an upper surface of the second electrode 218 are facing a lower surface of the membrane 211.

The conducting membrane 211 is effectively grounded via capacitive coupling to one of: the vacuum chamber 130, or the supporting stage 106.

The membrane 211 is pre-stressed (e.g. to a tension of 100-1000 MPa, such as 300-500 MPa). The membrane 211 has a thickness of 5-50 nm, typically 10-30 nm. The inner portion of the membrane 211 is free to mechanically oscillate above the moveable stage 106.

In use, the moveable stage 106 is configured to move in two dimensions in the plane of the conducting frame 108. Movements of the moveable stage 106 are configured to also move the conducting frame 108 and the membrane 211, to enable the membrane 211 to be moved within the cleaning apparatus 100.

In use, the first linear actuator 112 and the second linear actuator 212 are operable to move independent of one another in one dimension perpendicular to the plane of the conducting frame 108.

In use, the first linear actuator 112 is operable to move the first connector 114. The first connector 114 is arranged to provide a mechanical reference to the first electrode 118 and the first proximity sensor 116. Consequently, the first linear actuator 112 is operable to move the first electrode 118 and the first proximity sensor 116 relative to the membrane 211. The first connector 114 comprises an insulator configured to electrically insulate the first electrode 118 and the first proximity sensor 116 from the first linear actuator 112.

In use, the second linear actuator 212 is operable to move the second connector 214. The second connector 214 is arranged to provide a mechanical reference to the second electrode 218 and the second proximity sensor 216. Consequently, the second linear actuator 212 is operable to move the second electrode 218 and the second proximity sensor 216 relative to the membrane 211. The second connector 214 comprises an insulator configured to electrically insulate the second electrode 218 and the second proximity sensor 216 from the second linear actuator 212.

In use, the first linear actuator 112 and the second linear actuator 212 are respectively configured to move the first proximity sensor 116 and the second proximity sensor 216 to be equidistant from the membrane 211. In use, the first linear actuator 112 and the second linear actuator 212 are respectively configured to move the first electrode 118 and the second electrode 218 to be equidistant from the membrane 211.

Having the first electrode 118 and the second electrode 218 equidistant from the membrane 211 enables an excitation of the membrane 211 to be balanced. For example, while active, the electrodes 118, 218 exert force on the membrane 211 in opposite directions and a time-averaged force on the membrane 211 from the electrodes 118, 218 combined is less than 10% (e.g. preferably less than 1%) of a time-averaged force from any one of the electrodes 118, 218.

In use, the moveable stage, the first linear actuator 112 and the second linear actuator 212 are operable to position the first cleaning part 110 and the second cleaning part 210 relative to the membrane 211 in three dimensions.

In use, the first voltage source 111 is arranged to apply a first voltage to the first electrode 118 and the second voltage source 211 is arranged to apply a second voltage to the second electrode 218. The first voltage and the second voltage are with respect to the ground (not shown). The first electrode 118 and the second electrode 218 are configured to generate a time-varying electric field proximate to the membrane 211.

The first isolator 115 comprises an insulator configured to electrically insulate the first electrode 118 from the first proximity sensor 116. The second isolator 215 comprises an insulator configured to electrically insulate the second electrode 218 from the second proximity sensor 216.

In use, the first proximity sensor 116 is configured to measure a distance between the first proximity sensor 116 and a surface of the membrane 211 closest to the first proximity sensor 116. The first proximity sensor 116 is configured to illuminate the membrane 211 with a first measurement beam 117 and measure at least one property of a portion of the first measurement beam 117 reflected by the membrane 211, to measure the distance between the first proximity sensor 116 and the surface of the membrane 211 closest to the first proximity sensor 116. The first proximity sensor 116 is configured to provide the controller 190 with data corresponding to the distance between the first proximity sensor 116 and the surface of the membrane 211 closest to the first proximity sensor 116.

In use, the second proximity sensor 216 is configured to measure a distance between the second proximity sensor 216 and a surface of the membrane 211 closest to the second proximity sensor 216. The second proximity sensor 216 is configured to illuminate the membrane 211 with a second measurement beam 217 and measure at least one property of a portion of the second measurement beam 217 reflected by the membrane 211, to measure the distance between the second proximity sensor 216 and the surface of the membrane 211 closest to the second proximity sensor 216. The second proximity sensor 216 is configured to provide the controller 190 with data corresponding to the distance between the second proximity sensor 216 and the surface of the membrane 211 closest to the second proximity sensor 216.

The proximity sensors 116, 216 are used (e.g. in conjunction with the controller 190) to position the electrodes 118, 218 with respect to the membrane 211 with an accuracy of 10 μm. This is the highest accuracy required at the lowest reasonable gap (i.e. between the membrane 211 and the electrodes 118, 218) and includes a safety margin for inaccuracies associated with localised portions of the membrane 211 deviating from an overall plane of the membrane and tilt of the moveable stage 106 and tile of the conducting frame 108).

In use, the proximity sensors 116, 216 are operable to sense the displacement of the membrane more frequently than a frequency of low eigenmodes of mechanical oscillations in the membrane 211. The low eigenmodes of the membrane 211 refer to at least one of the following mechanical oscillation eigenmodes of the membrane: mode 1 (i.e. a fundamental/monopole mode), mode 2 (e.g. dipole, long edge of pellicle), mode 3 (e.g. dipole, short edge of pellicle), mode 4 (e.g. quadruple), etc. As an example, such low eigenmodes are in a range of 1-3 kHz.

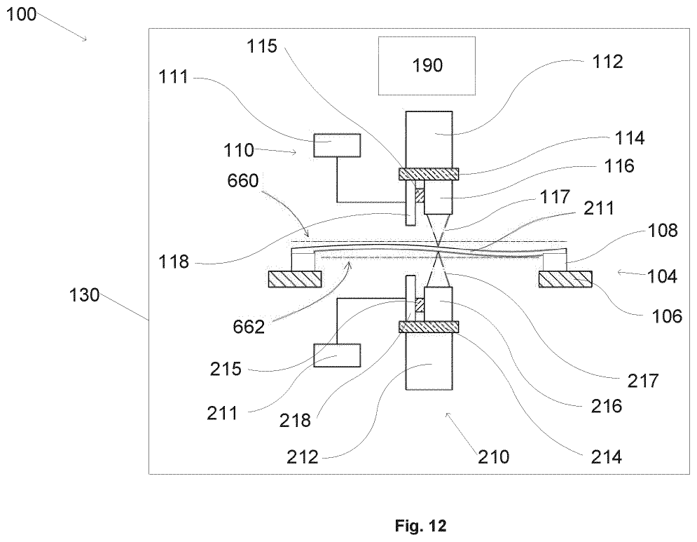

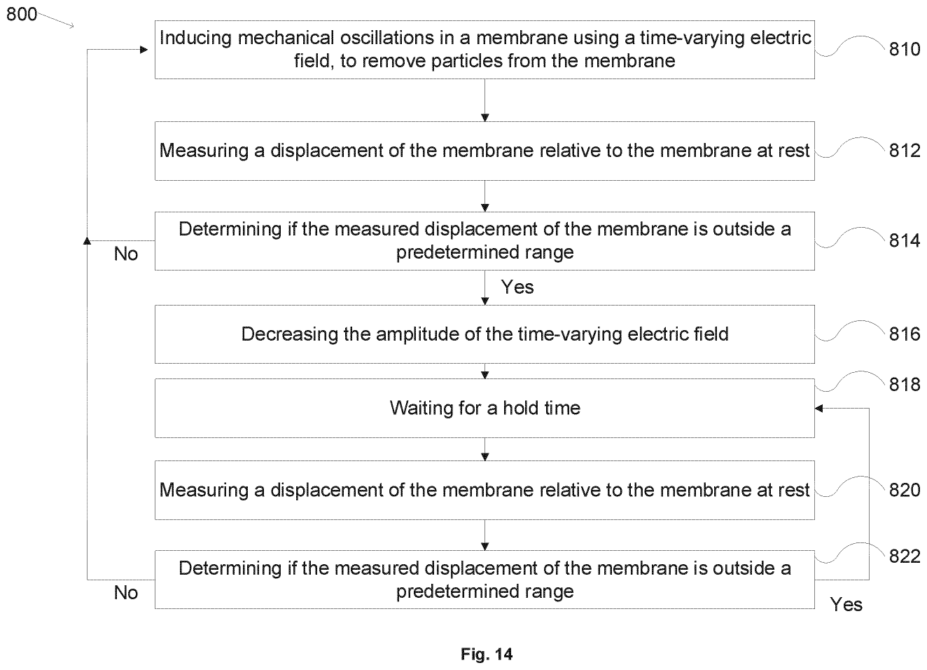

Having the proximity sensors 116, 216 operable to sense the displacement of the membrane 211 more frequently than the low eigenmodes enables the use of a controller 190 controlled feed-back loop, wherein mechanical oscillations of the membrane 211 are monitored and the controller controls at least one characteristic of the time-varying electric field (i.e. generated by the electrodes 118, 218) if the measured displacement of the membrane 211 is outside a predetermined range (see FIG. 12). Such feed-back loops are described in relation to FIGS. 14-16.

In use, the proximity sensors 116, 216 are operable to measure the displacement of the membrane 211 more frequently than at least one of: 0.1 kHz, 1 kHz, 10 KHz.

In use, the proximity sensors 116, 216 are operable to measure the displacement of the membrane 211 less frequently than at least one of: 1 kHz, 10 kHz, 100 kHz, 1000 kHz.

The first electrode 118 (e.g. in the form of the combined excitation/collector electrode) and the membrane 211 are not part of a closed circuit. Therefore, in use, electric charge can build-up on the first electrode 118 and on the membrane 211 when voltage is applied by the first voltage source 111. The second electrode 218 (e.g. in the form of the combined excitation/collector electrode) and the membrane 211 are not part of a closed circuit. Therefore, in use, electric charge can build-up on the second electrode 218 and on the membrane 211 when voltage is applied by the second voltage source 211. This effect is similar to the charging of opposing plates in a capacitor.

In use, the first voltage source 111 and the second voltage source 211 are respectively configured to apply voltage to the first electrode 118 and the second electrode 218 alternately (e.g. such that a net electrostatic force is applied to the membrane 211 at any instantaneous time). Alternatively, the first voltage source 111 and the second voltage source 211 are respectively configured to apply opposite voltages to the first electrode 118 and the second electrode 218 (e.g. to apply a net electrostatic force to the membrane 211).

Electric charge build-up on the first electrode 118 and the membrane 211 creates an electrostatic attractive force between the first electrode 118 and the membrane 211. Electric charge build-up on the second electrode 218 and the membrane 211 creates an electrostatic attractive force between the second electrode 218 and the membrane 211. Since the membrane 211 is relatively thin and, therefore, flexible, the membrane 211 will be distorted by this attractive force.

The build-up of electric charge, giving rise to electrostatic forces in the vicinity of a membrane assembly 104, is exploited in some embodiments of the current invention. Specifically, mechanical oscillations are induced in the membrane 211 by configuring temporal characteristics of said electrostatic forces. This is achieved according to the current embodiment of the invention by applying a time-varying voltage across the first electrode 118, the second electrode 218, and the membrane 211. The time-varying voltage utilised for this purpose comprises a plurality of temporally spaced pulses. This mechanism is described in detail below in relation to FIGS. 11a-11b.

The time-varying voltage applies pressure pulses having an electrostatic pressure of 10-1000 Pa, for example 100 Pa. The time-varying voltage applies pressure pulses with a duration of 10-1000 ns, for example 100 ns. The time-varying voltage has an average repetition rate of 10-1000 kHz, for example, 100 kHz. The time-varying voltage has a peak pulse repetition rate varied in a range 0.1-10 MHz, to overlap a first/second/third harmonic frequency with a resonance of the particle, that can be treated for simplicity as a mass on a massless spring, for optimal resonance excitation.

The pressure pulses and the time-varying voltage have identical duration. The time-varying voltage (e.g. voltage pulses) are applied to electrodes having a cross-section S≅1 to 5000 mm\hat{ }2 for example S≅10 to 1000 mm\hat{ }2. To provide a required electrostatic pressure (P=½ ε_0 E\hat{ }2≅100 Pa), the electrode(s) are positioned (h) within 0.5 mm to 2.5 mm from the membrane.

One or more vacuum pumps (not shown) may be provided to control a pressure within the vacuum chamber 130. In particular, a vacuum pump apparatus (not shown) may be used to lower the pressure of the vacuum chamber 130 to near vacuum conditions. For example, the one or more vacuum pumps are operable to reduce the pressure within the vacuum chamber 130 to <10⁻³ mBar, preferably to <10⁻⁶ mBar. The pressure of the vacuum chamber 130 is configured to be equal on opposite sides of a plane of the membrane 211 (e.g. which is parallel to the plane of the conducting frame 108).

The controller 190 is electrically connected to the first proximity sensor 116, the second proximity sensor 216, the first voltage source 111, and the second voltage source 211. In use, the controller 190 is operable to control the first electrode 118 and the second electrode 218 to alter at least one characteristic (e.g. an amplitude, a frequency, a phase) of the time-varying electric field generated by the first electrode 118 and the second electrode 218 in the vicinity of the membrane 211 based at least on a measured displacement of the membrane 211 that is measured by the first proximity sensor 116 and the second proximity sensor 216.

The low eigenmodes to be suppressed are large (i.e. in amplitude), meaning that it is unimportant that each proximity sensor 116, 216 is removed from its respective electrode 118, 218, as the distance between each proximity sensor 116, 216 and its respective electrode 118, 218 is much smaller than a wavelength of the mechanical oscillation modes to be suppressed.

The membrane cleaning apparatus 100 may be used for cleaning a membrane 211, as now discussed. In use, the membrane cleaning apparatus 100 is configured to clean a first localised portion of the membrane 211 then to use the moveable stage 106 to position a second localised portion for cleaning. After cleaning the second localised portion of the membrane 211, the moveable stage 106 is used to position a third localised portion for cleaning, and this cycle repeats until the entire membrane 211 has been cleaned. The localised portions are typically larger than the electrode 118, 218. Typically, each localised portion of the membrane 211 overlaps with at least one adjacent localised portion of the membrane,

The membrane 211 may be a pellicle membrane 16 and may be formed from a material with high or moderate electrical conductivity, such as doped polycrystalline silicon, or metal silicide, or doped metal silicide, or doped metal carbide, or doped metal nitride, or a combination of any of the above materials.

In particular, the apparatus 100 is suitable for preventing damage to the membrane 211 resulting from a mechanical oscillation amplitude of the membrane 211 exceeding a predetermined range. Damage to the membrane 211 includes tearing or breaking of the membrane 211. Run-away failure causes the damage to the membrane 211. For example, if deformation of the membrane 211 relative to the membrane 211 at rest exceeds the predetermined range, a stiffness of the membrane 211 is unable to resist the electrostatic force from the nearer one of the first electrode 118 or the second electrode 218. In this case, the membrane 211 deforms further until the membrane 211 touches one of the electrodes 118, 218 and breaks either mechanically or via a spark.

The apparatus 100 is operable to prevent such run-away failure to prevent damage to the membrane 211.

FIG. 10 shows a cross-section through a membrane 211 being cleaned by the membrane cleaning apparatus 100 when a voltage provided by the voltage source 211 is applied across the combined excitation/collector electrode 218 and the conducting frame 108. For clarity, FIG. 10 and FIGS. 11a-11c are described in relation to using a single cleaning part 210 instead of using two cleaning parts 110, 210. Also shown is a particle 240 disposed on the membrane 211. As the membrane 211 is generally flexible and the combined excitation/collector electrode 218 is generally rigid, the electrostatic attractive force between the combined excitation/collector electrode 218 and the membrane 211 creates mechanical deformations 301 in the membrane 211.

In an embodiment of the invention, the voltage applied across the combined excitation/collector electrode 218 and the conducting frame 108 can follow the waveform 400 shown in FIG. 11a, which shows a plot of voltage, V, as a function of time, t. The voltage is time-varying. Specifically, the waveform 400 of the voltage is periodic such that the voltage may be described as a pulsed voltage 401. The pulsed voltage 401 comprises alternating on-portions 402 and off-portions 403. It will be appreciated that the voltage waveform 400 shown in FIG. 11a is only an example of a pulsed voltage 401 that may be generated by the voltage source 211. In other embodiments it is possible to use alternative pulse shapes and pulse repetition frequencies, and/or pulse patterns, such as bursts, trains.

The pulsed voltage 401 shown in FIG. 11a comprises a DC component (where off-portions 403 correspond to a non-zero potential difference between the combined excitation/collector electrode 218 and the conducting frame 108). In an alternative embodiment, a similar waveform 400 but with no DC component (where off-portions 403 correspond to zero potential difference between the combined excitation/collector electrode 218 and the conducting frame 108) may be used. Using the pulsed voltage 401 with a DC component generates a stronger time-averaged electric field between the combined excitation/collector electrode 218 and the membrane assembly 208, which may improve particle 240 transport towards the combined excitation/collector electrode 218, as described below.

The pulsed voltage 401 creates a pulsed electrostatic attractive force between the combined excitation/collector electrode 218 and the membrane 211. During the on-portions 402 of the pulsed voltage 401, there is an electrostatic attractive force between the combined excitation/collector electrode 218 and the membrane 211, resulting in mechanical deformations 301 of the membrane 211 as described above. The pulsed pressure giving rise to such an electric force (charge) may typically be between 0.01 Pa and 100 Pa. Following the applied pressure, all or at least some portions of the membrane are accelerated towards an electrode 218.

During the off-portions 403 of the pulsed voltage 401 with a DC component, there is a reduced electrostatic attractive force between the combined excitation/collector electrode 218 and the membrane 211 compared with during the on-portions 402. For embodiments with no DC component to the pulsed voltage 401, during the off-portions 403 of the pulsed voltage 401, there is no electrostatic attractive force between the combined excitation/collector electrode 218 and the membrane 211. Therefore, during the off-portions 403 of the pulsed voltage 401 (whether comprising a DC component or not), tension of the membrane 211 can result in acceleration of the membrane 211 in the opposite direction of the mechanical deformations 301 caused during the on-portions 402 of the pulsed voltage 401. As the on-portions 402 and off-portions 403 of the pulsed voltage 401 are repeated, mechanical oscillations are induced in the membrane 211.

In an embodiment of the invention, the voltage applied across the combined excitation/collector electrode 218 and the conducting frame 108 has a duty cycle of less than 10%. Advantageously, this limits the amount of heating up of the membrane 211 by the current charging and discharging the capacitor formed by the membrane 211 and the combined excitation/collector electrode 218.

Particles 210 may be present on the surface of the membrane 211 that faces the combined excitation/collector electrode 218.

Averaged over time there is a net electric field between the combined excitation/collector electrode 218 and the membrane assembly 208 due to the pulsed voltage 400.

A particle 240 with non-zero surface conductivity disposed on the surface of the membrane 211 that faces the combined excitation/collector electrode 218 may have acquired an electric charge from the membrane 211 due to the pulsed voltage 401. The electric charge of said particle 240 is such that an electrostatic force exists which attracts the particle 240 towards the combined excitation/collector electrode 218.

Additionally or alternatively, a particle 240 may have acquired an electric charge through triboelectric interactions with the surface of the membrane 211 that faces the combined excitation/collector electrode 218. The electric charge of said particle 240 may be either positive or negative. In use, polarity of the voltage pulses 400 may be chosen, so to provide attractive force between tribo-charged particles and electrode 218; to cover the situations of different materials (different sign of tribo-charge) the polarity of voltage pulses (DC component and/or pulse component) may be varied.

Each particle 240 present on a surface of the membrane 211 will generally move with the surface of the membrane 211 as the membrane oscillates, due to van der Waals attractions between the particle 240 and the surface of the membrane 211 on which the particle 240 is situated.

Each particle 240 on a membrane 211 under pre-tension can be treated as an independent oscillator. Resonant frequencies of such oscillators may vary with properties of the particle 240 and of the membrane 211.

For example, resonant frequencies of such particles 210 may vary with mass of the particle 240, M. Resonant frequencies may vary with d: the ratio of the radius of vibration 303 induced in the membrane 211 (defined by the amplitude of oscillations and excitation frequency) to the size of the contact spot 304 (defined by the typical, short range van der Waals interaction) of the particle 240 on the membrane 211. Typically, for a membrane 211 being cleaned using the membrane cleaning apparatus 100, d may be between 100 and 1000,000. Resonant frequencies of such particles may also vary with the thickness 305 of the membrane 211, h. Typically, for a membrane 211 being cleaned using the membrane cleaning apparatus 100, h may be between 10 nm and 100 nm. Resonant frequencies may also vary with the pre-tension of the membrane 211, σ. Typically, for a membrane 211 being cleaned using the membrane cleaning apparatus 100, σ may be between 50 MPa and 500 MPa.

The fundamental frequency of oscillators, v₀, may be described by the following equation:

$$\\ {v}_{0} ≅ \sqrt{σ \frac{h}{2 π M ln ( d )}} .$$

For typical particle density and for particle radius between 0.5 μm and 5 μm, v₀ may be between approximately 10 MHz and 0.3 MHz. If an excitation frequency applied to the membrane 211 approaches a resonant frequency of a particle 240, the amplitude 301 of oscillation of the particle 240 can increase. As the amplitude of the oscillation of the particle 240 increases, the membrane-particle separation 302 may likewise increase, since inertia due to particle acceleration may exceed van der Waals force.

The magnitude of van der Waals forces is inversely proportional to the square of the separation 302 between atoms or molecules on which the forces act. At some threshold membrane-particle separation 302, van der Waals attractions between the particle 240 and the surface of the membrane 211 are attenuated to the extent that an electrostatic force that attracts the particle 240 towards the combined excitation/collector electrode 218 (i.e., away from the membrane 211) overcomes van der Waals forces between the particle 240 and the membrane 211. Above said threshold membrane-particle separation 302, the particle 240 may therefore be removed from the membrane 211. The particle 240 will thereon be disposed within the space between the membrane 211 and the combined excitation/collector electrode 218 and will accelerate towards the combined excitation/collector electrode 218.

Resonant frequencies of a particle 240 vary with the size of the particle 240 due to mass dependency. In order to remove particles 210 that have a range of sizes, the pulsed voltage 401 may be configured to induce a range of frequencies of oscillation of the membrane 211. The range of frequencies of induced oscillation of the membrane 211 may be referred to as an “excitation spectrum”. The excitation spectrum is given by a Fourier transform of the waveform 400 of the pulsed voltage 401 applied by the voltage source 211. Components of the excitation spectrum arise from temporal features of the pulsed voltage 401. Features that repeat with a relatively long time period give rise to components of the excitation with at a relatively low frequency, and vice versa.

FIGS. 11b and 11c show schematic plots of an excitation spectrum 404 corresponding to a pulsed voltage 401 of the form shown in FIG. 11a. The excitation spectra 404 schematically show relative electrostatic attractive force exerted on the membrane, F, as a function of the oscillating frequency at which this force is exerted, f. The excitation spectra 404 comprise a first portion 405 and a second portion 406.

The first portion 405 of the excitation spectrum 404 arises from the temporal feature of the pulsed voltage 401 with the longest duration: the time period 407 of pulses of the pulsed voltage 401. The central frequency 408 of the first portion 405 is defined by the inverse of the time period 407 (this central frequency 408 may be referred to as the pulse frequency or repetition rate). In some embodiments, the repetition rate of the pulsed voltage 401 may be in the range 30 kHz to 30 MHz. The shaded region 409 of FIG. 11c corresponds to shifting the central frequency 408 of the first portion 405 via modulating the time period 407. An increase in the time period 407 leads to a reduction in the central frequency 408 of the first portion 405 (and vice versa).

The second portion 406 of the excitation spectrum 404 arises from temporal features of the pulsed voltage 401 with shorter duration than the time period 407. The second portion 406 is defined by: the full width at half maximum (FWHM) 410 of the on-portions 402 of pulses of the pulsed voltage 401; and the rise time 411 and fall time 412 of pulses of the pulsed voltage 401. The lower frequency 413 of the second portion 406 is defined by the inverse of the FWHM 410. The upper frequency 414 of the second portion 406 is defined by the inverse of whichever is the shortest duration out of the rise time 411 and fall time 412. The shaded region 415 of FIG. 11c corresponds to shifting the lower frequency 413 and the upper frequency 414 of the second portion 406 via modulating the FWHM 410 and rise time 411 and fall time 412. An increase in the FWHM 410 leads to a reduction in the lower frequency 413 of the second portion 406 (and vice versa). An increase in whichever is the shortest duration out of the rise time 411 and fall time 412 leads to a reduction in the upper frequency 414 of the second portion 406 (and vice versa).

The pulsed voltage 401 of the form shown in FIG. 11a is relatively simple. It may therefore be implemented easily by a person skilled in the art. Advantageously, though the waveform 400 of the pulsed voltage 401 is simple, it offers several configurable parameters (including time period 407, FWHM 410, rise time 411, and fall time 412), which can be chosen (and varied) to achieve a desired excitation spectrum.

Alternatively to using a pulsed voltage 401 of the form shown in FIG. 11a, an arbitrary function generator connected to a voltage amplifier may be used to generate any desired pulse shape, configurable to induce a desired excitation spectrum.

In this embodiment, the voltage waveform 400 shown in FIG. 11a may be considered to be of a general shape and having one or more parameters (for example any of the time period 407, FWHM 410, rise time 411, and fall time 412), which can be chosen (and varied) to achieve a desired excitation spectrum. It will be appreciated that in other embodiments, different voltage waveforms may be used but which also can be considered to have a general shape and have one or more parameters which can be chosen (and varied) to achieve a desired excitation spectrum.

In an arrangement of the current embodiment, the combined excitation/collector electrode 218 and the membrane assembly 208 are disposed so that the separation between the combined excitation/collector electrode 218 and the membrane 211 is between 0.5 mm and 2.5 mm.

In an arrangement of the current embodiment, the pulsed voltage 401 applied across the combined excitation/collector electrode 218 and the conducting frame 108 has a maximum potential difference of between 100 V and 10000 V.

In an arrangement of the current embodiment, the net (time-averaged) electric field between the combined excitation/collector electrode 218 and the membrane assembly 208 (due to the pulsed voltage 401) has a field strength greater than 10 V m⁻¹ or less than-10 V m⁻¹.

In an arrangement of the current embodiment, the pulsed voltage 401 is configured to excite oscillations of the membrane 211 (and thereby particles 210 disposed on the membrane 211) in a frequency range of between 30 kHz and 30 MHz. For example, the pulsed voltage 401 may be configured to excite oscillations of the membrane 211 in a frequency range of between 100 kHz and 10 MHz.

In an arrangement of the current embodiment, the pulsed voltage 401 is not a sinusoidally varying voltage. By ensuring that appropriate off-sections 403 are incorporated into the shape of the pulse, dissipated power into the conducting coating 209 on the membrane assembly 208 may be kept low. This is useful to allow radiative cooling to maintain the temperature of the membrane 211 within safe limits.

Using the arrangements described above, particles 210 with a dimension between 0.5 and 5 μm can be removed from the membrane 211 using the membrane cleaning apparatus 100.

The pulsed voltage 401 may be applied as separate trains of pulses. One train of pulses may immediately follow another train of pulses. Separate trains of pulses may be applied with the polarity of the pulsed voltage reversed in successive trains of pulses. This may be useful to release both negatively charged and positively tribo-charged particles and attract them to the collecting electrode. The duration of each train of pulses may be configured so that particles 210 have enough time to be transported to the combined excitation/collector electrode 218 before the next train of pulses (with reversed voltage polarity) is applied. It will be appreciated that charged particles may generally discharge upon contact with the excitation/collector electrode 218. Therefore, these particles are not transported back to the membrane 211 when the polarity of the voltage is reversed.

FIG. 12 shows an identical cross-section through the membrane cleaning apparatus 100 to FIG. 9, except that the membrane 211 in FIG. 12 is mechanically oscillating instead of stationary. Consequently, the membrane 211 of FIG. 12 deviates from a rest plane of the membrane 211.

Also shown in FIG. 12 is a predetermined range in the form of an acceptable oscillation zone of the membrane 211 that is defined between an upper critical deviation plane 660 and a lower critical deviation plane 662. The upper critical deviation plane 660 and the lower critical deviation plane 662 are disposed parallel to the plane of the conduction frame 108. The upper critical deviation plane 660 is disposed closer to the first cleaning part 110 and the lower critical deviation plane 662 is disposed closer to the second cleaning part 210. The upper critical deviation plane 660 and the lower critical deviation plane 662 correspond to displacements of the membrane 211 that are large enough to risk damage to the membrane 211 as a result of run-away failure.

The predetermined displacement range comprises displacement of at least the localized portion of the membrane 211 relative to the membrane 211 at rest having a smaller magnitude than at least one of: 10 μm, 100 μm, 1000 μm.

In use, the first displacement sensor 116 is measuring the displacement of a localised portion of the membrane 211 that is closest to the first displacement sensor 116. If a maximum amplitude of the mechanically oscillating membrane 211 becomes large enough that the first displacement sensor 116 measures the displacement of the localised portion of the membrane 211 relative to the membrane 211 at rest to be closer to the first displacement sensor 116 than the upper critical deviation plane 660, the controller 190 controls at least one characteristic of the time-varying electric field generated by the first electrode 118 and the second electrode 218.

In use, the second displacement sensor 216 is measuring the displacement of a localised portion of the membrane 211 that is closest to the second displacement sensor 216. If the maximum amplitude of the mechanically oscillating membrane 211 becomes large enough that the second displacement sensor 216 measures the displacement of the localised portion of the membrane 211 relative to the membrane 211 at rest to be closer to the second displacement sensor 216 than the lower critical deviation plane 662, the controller 190 controls at least one characteristic of the time-varying electric field generated by the first electrode 118 and the second electrode 218.

The controller 190 controls at least one characteristic of the time-varying electric field generated by the first electrode 118 and the second electrode 218 by controlling the first voltage source 111 and the second voltage source 211. The characteristic of the time-varying electric field generated by the first electrode 118 and the second electrode 218 is at least one of an amplitude, a frequency, a phase.

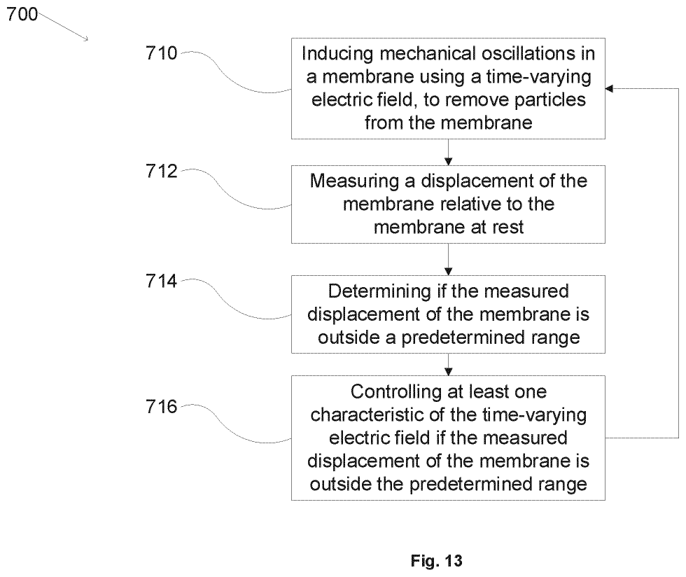

The at least one characteristic of the time-varying electric field generated by the first electrode 118 and the second electrode 218 is controlled according to at least one of the embodiments described in relation to FIGS. 13-16.

FIG. 13 shows a flow-chart describing a method 700 of removing particles from a membrane 211, according to another embodiment. The method 700 is suitable to prevent such run-away failure as described in relation to FIG. 9, to prevent damage to the membrane 211.

The method 700 comprises steps 710, 712, 714, 716, which are: inducing mechanical oscillations in a membrane using a time-varying electric field, to remove particles from the membrane 710; measuring a displacement of the membrane relative to the membrane at rest 712; determining if the measured displacement of the membrane is outside a predetermined range 714; and controlling at least one characteristic of the time-varying electric field if the measured displacement of the membrane is outside the predetermined range 716.

The steps 710, 712, 714, and 716 are performed sequentially. The step 710 is performed after the step 716, such that the method 700 forms a loop of steps 710, 712, 714, and 716.

FIG. 14 shows a flow-chart describing a method 800 of removing particles from a membrane 211, according to another embodiment. The method 800 is suitable to prevent such run-away failure as described in relation to FIG. 9, to prevent damage to the membrane 211.

The method 800 comprises steps 810, 812, 814, 816, 818, 820, and 822, which are: inducing mechanical oscillations in a membrane using a time-varying electric field, to remove particles from the membrane 810; measuring a displacement of the membrane relative to the membrane at rest 812; determining if the measured displacement of the membrane is outside a predetermined range 814; decreasing the amplitude of the time-varying electric field 816; waiting for a hold time 818; measuring a displacement of the membrane relative to the membrane at rest 820; and determining if the measured displacement of the membrane is outside a predetermined range 822.

Step 810 is performed first followed by step 812 and then step 814. If in step 814 it is determined that the measured displacement of the membrane 211 is not outside the predetermined range, the method 800 loops back to step 810. If in step 814 it is determined that the measured displacement of the membrane 211 is outside the predetermined range, step 816 is performed. Step 816 is followed by step 818 then 820 then step 822. If in step 822 it is determined that the measured displacement of the membrane 211 is not outside the predetermined range, the method 800 loops back to step 810. If in step 822 it is determined that the measured displacement of the membrane 211 is outside the predetermined range, the method 800 loops back to step 818.

The step 816 (i.e. decreasing the amplitude of the time-varying electric field) is performed, using the controller 190, by at least one of: decreasing the voltage applied to the first electrode 118 and the second electrode 218 by the first voltage source 111 and the second voltage source 211 respectively; or stopping the voltage applied to the first electrode 118 and the second electrode 218 by the first voltage source 111 and the second voltage source 211 respectively.

The step 818 (i.e. waiting for a hold time) is performed to enable the mechanical oscillation amplitude of the membrane 211 to decrease. The hold time is at least one of: a predetermined amount of time; or is determined based on the measurement of the displacement of the membrane 211 relative to the membrane 211 at rest. For example, the hold time is 10-100 s.

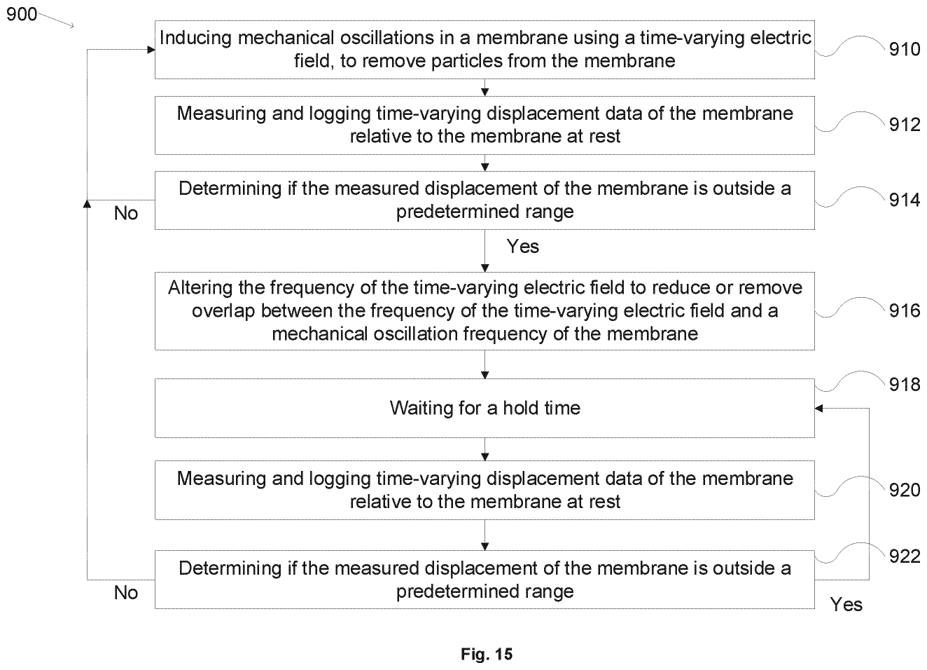

FIG. 15 shows a flow-chart describing a method 900 of removing particles from a membrane 211, according to another embodiment. The method 900 is suitable to prevent such run-away failure as described in relation to FIG. 9, to prevent damage to the membrane 211.

The method 900 comprises steps 910, 912, 914, 916, 918, 920, and 922, which are: inducing mechanical oscillations in a membrane using a time-varying electric field, to remove particles from the membrane 910; measuring and logging time-varying displacement data of the membrane relative to the membrane at rest 912; determining if the measured displacement of the membrane is outside a predetermined range 914; altering the frequency of the time-varying electric field to reduce or remove overlap between the frequency of the time-varying electric field and a mechanical oscillation frequency of the membrane 916; waiting for a hold time 918; measuring and logging time-varying displacement data of the membrane relative to the membrane at rest 920; and determining if the measured displacement of the membrane is outside a predetermined range 922.

The steps 910, 914, 918, and 922 are identical to the steps 810, 814, 818, and 822 respectively.

The steps 912 and 920 include logging time-varying displacement data of the membrane 211 relative to the membrane 211 at rest. Logging this time-varying displacement data involves measuring and storing displacement data of the membrane 211 and corresponding time stamps, wherein each time stamp corresponds to when the each displacement datum of the membrane 211 was measured. Logging this time-varying displacement data involves storing the time-varying displacement data such that the time-varying displacement data are retrievable in step 916.

The step 916 (i.e. altering the frequency of the time-varying electric field to reduce or remove overlap between the frequency of the time-varying electric field and a mechanical oscillation frequency of the membrane 211) is performed by: retrieving the logged time-varying displacement data; transforming the time-varying displacement data to a frequency domain using a Fourier transform and extracting at least one mechanical oscillation frequency of the membrane; determining or retrieving predetermined values for low mechanical oscillation eigenmodes of the membrane 211; and altering the frequency of the time-varying electric field to reduce or remove overlap between the frequency of the time-varying electric field and the low eigenmodes of the membrane 211.

Reducing or removing overlap between the frequency of the time-varying electric field and the low eigenmodes of the membrane 211 comprises altering, using the controller 190, the frequency of the voltage applied to the first electrode 118 and the second electrode 218 by the first voltage source 111 and the second voltage source 211 respectively.

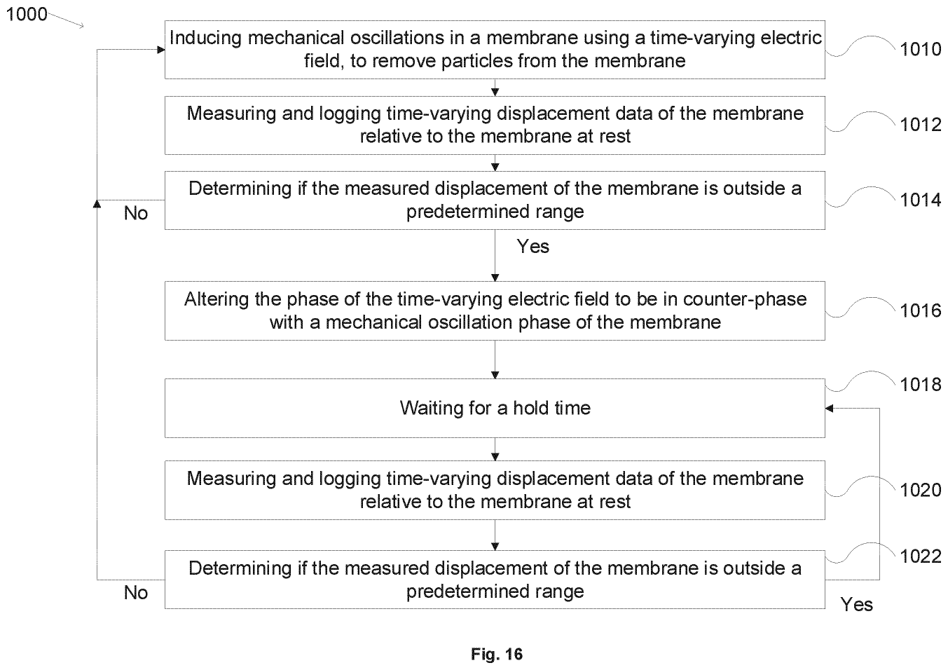

FIG. 16 shows a flow-chart describing a method 1000 of removing particles from a membrane 211, according to another embodiment. The method 1000 is suitable to prevent such run-away failure as described in relation to FIG. 9, to prevent damage to the membrane 211.

The method 1000 comprises steps 1010, 1012, 1014, 1016, 1018, 1020, and 1022, which are: inducing mechanical oscillations in a membrane using a time-varying electric field, to remove particles from the membrane 1010; measuring and logging time-varying displacement data of the membrane relative to the membrane at rest 1012; determining if the measured displacement of the membrane is outside a predetermined range 1014; altering the phase of the time-varying electric field to be in counter-phase with a mechanical oscillation phase of the membrane 1016; waiting for a hold time 1018; measuring and logging time-varying displacement data of the membrane relative to the membrane at rest 1020; and determining if the measured displacement of the membrane is outside a predetermined range 1022.

The steps 1010, 1014, 1018, and 1022 are identical to the steps 810, 814, 818, and 822 respectively. The steps 1012 and 1020 are identical to the steps 912 and 920 respectively.

The step 1016 (i.e. altering the phase of the time-varying electric field to be in counter-phase with a mechanical oscillation phase of the membrane 211) is performed by: retrieving the logged time-varying displacement data; determining from the logged time-varying displacement data a mechanical oscillation phase of the membrane 211; and altering, using the controller 190, the phase of the voltage applied to the first electrode 118 and the second electrode 218 by the first voltage source 111 and the second voltage source 211 respectively such that the phase of the resultant time-varying electric field and the mechanical oscillation phase of the membrane 211 are in counter-phase.

The method 1000 enables the hold time (e.g. a recovery time for mechanical oscillations in the membrane 211 to subside such that the measured displacement of the membrane 211 is within the predetermined range) to be reduced relative to the methods 800, 900. This enables throughput of the membrane cleaning apparatus 100 to be increased.

The intrinsic damping of the membrane 211 is low, such that the hold time is, for example, 10-100 s. The method 1000 enables pressure induced on the membrane 211 to counter the measured displacement of the membrane 211 in real-time, which enables the hold time to be reduced by a factor 10-100× relative to relying on the intrinsic damping of the membrane 211. As such, the method 1000 is able to suppress mechanical oscillations faster than a time over which the mechanical oscillations were induced.

The method 1000 enables efficiency of the membrane cleaning apparatus 100 to be increased by reducing the gap between the membrane 211 and the electrodes 118, 218. For example, the cleaning pressure sequence could be performed in an intrinsically unstable configuration, provided that the time-varying electric field could be provided in counter-phase to the mechanical oscillation phase of the membrane 211 quickly enough to prevent instability developing and to suppress mechanical oscillations of the membrane 211 before an amplitude of the mechanical oscillations becomes critical (i.e. before the measured displacement of the membrane 211 exceeds the predetermined range).

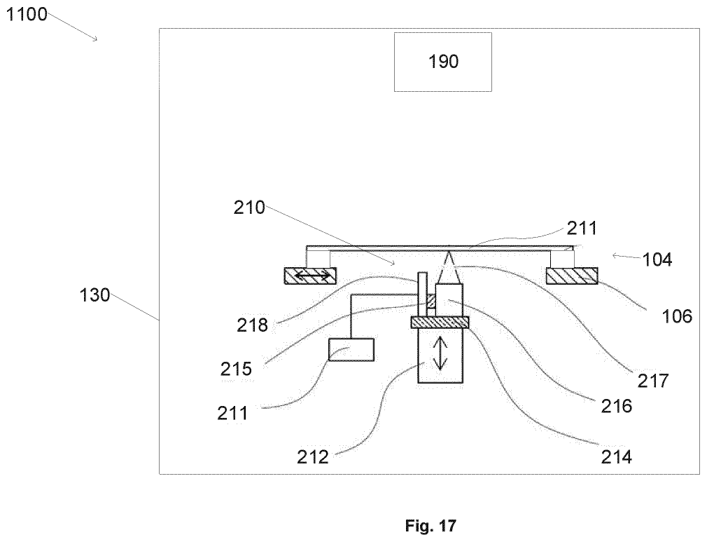

FIG. 17 shows an alternative embodiment of a membrane cleaning apparatus 1100 according to the invention, and a membrane 211. The apparatus 1100 of FIG. 17 is identical to the apparatus 100 or FIG. 9, except that the apparatus 1100 does not have the first cleaning part 110.

It should be understood that the different apparatus and methods described above are illustrative only and that the claims are not limited to the apparatus and methods described above. Those skilled in the art will understand that various modifications may be made to the apparatus and methods described above without departing from the scope of the appended claims.

For example, in relation to FIG. 9, instead of the membrane 211 being grounded to the ground by capacitive coupling directly from the conducting coating 209 to the ground over a gap (e.g. of 1-10 cm), the membrane 211 may be grounded to the ground by capacitive coupling via the conducting frame 108 and/or the moveable stage 106.

In relation to FIG. 9, instead of the membrane 211 being grounded to the ground by capacitive coupling directly from the conducting coating 209 to the ground over a gap (e.g. of 1-10 cm), the membrane 211 may be grounded via an electrical wire that connects the outer portion of the conducting coating 209 to the ground.

In relation to FIG. 9, instead of the membrane 211 being grounded, the membrane 211 may be DC biased relative to the ground.

In relation to FIG. 9, instead of the proximity sensors 116, 216 being operable to sense the displacement of the membrane 211 more frequently than a frequency of the low mechanical oscillation eigenmodes of the membrane 211, relatively slower proximity sensors may be used. The relatively slower proximity sensors may be operable to sense the displacement of the membrane 211 substantially as frequently as the frequency of the low eigenmodes of mechanical oscillations in the membrane 211.

Because the linear actuators 112, 212 are not used during membrane 211 cleaning and the moveable stage 106 moves slowly (e.g. below 100 μm/s) relative to the mechanical oscillation frequencies of the membrane 211, changes measured by the proximity sensors 116, 216 are attributable to mechanical oscillations in the membrane 211.

The proximity sensors 116, 216 may be operable to measure the displacement of the membrane 211 more frequently than at least one of: 100 Hz, 1000 Hz, 10,000 Hz.

The proximity sensors 116, 216 may be operable to measure the displacement of the membrane 211 less frequently than at least one of: 1000 Hz, 10,000, 100,000 Hz.

In relation to FIG. 9, instead of the proximity sensors 116, 216 being used for sensing mechanical oscillations in the membrane 211 and for setting the gap between the electrodes 118, 218 and the membrane 211, additional proximity sensors may be provided to proximity sensors 116, 216.

The additional proximity sensors may be used for sensing mechanical oscillations in the membrane 211 and the proximity sensors 116, 216 used for setting the gap between the electrodes 118, 218 and the membrane 211. Measurement of the mechanical oscillations in the membrane 211 and the gap between the electrodes 118, 218 and the membrane 211 may be made alternately. This may enable more frequent displacement measurements to be made at the expense of an absolute accuracy of each individual displacement measurement, which is preferred if the amplitude of mechanical oscillations is large (e.g. >200 μm).

In relation to method 800, instead of the method 800 looping back from step 822 to step 818 if it is determined that the measured displacement of the membrane 211 is outside the predetermined range, the method 800 may loop back to step 816.

In relation to method 900, instead of the method 900 looping back from step 922 to step 918 if it is determined that the measured displacement of the membrane 211 is outside the predetermined range, the method 900 may loop back to step 916.

In relation to method 1000, instead of the method 1000 looping back from step 1022 to step 1018 if it is determined that the measured displacement of the membrane 211 is outside the predetermined range, the method 1000 may loop back to step 1016.

In relation to method 1000, in addition to the step 1060 comprising altering the phase of the time-varying electric field to be in counter-phase with a mechanical oscillation phase of the membrane 211, an amplitude of the time-varying electric field may be increased such that a greater electrostatic force is applied to suppress mechanical oscillations of the membrane 211 faster than if the amplitude of the time-varying electric field were not increased.

In relation to methods 800, 900, and 1000, instead of controlling the at least one characteristic of the time-varying electric field in step 816, 916, and 1060, waiting for a hold time 818 (during which the maximum displacement of the membrane 211 returns to be within the predetermined displacement range), and subsequently reverting the at least one characteristic of the time-varying electric field to its value before the hold time in step 810, 910, 1010, the at least one characteristic of the time-varying electric field may be controlled until the method of removing particles from the membrane has been completed. Expressed differently, the at least one characteristic of the time-varying electric field may be controlled until a given localized portion of the membrane 211 has been cleaned or the entire membrane 211 has been cleaned.

Each feature disclosed or illustrated in the present specification may be incorporated in any of the different apparatuses and methods described above, either alone, or in any appropriate combination with any other feature disclosed or illustrated herein. One or more of the features of any of the apparatus or methods described above with reference to the drawings may produce effects or provide advantages when used in isolation from one or more of the other features of the same apparatus or method. Different combinations of the features are possible other than the specific combinations of the features of the apparatus and methods described above.

The skilled person will understand that in the preceding description and appended claims, positional terms such as ‘above’, ‘along’, ‘side’, etc. are made with reference to conceptual illustrations, such as those shown in the appended drawings. These terms are used for ease of reference but are not intended to be of limiting nature. These terms are therefore to be understood as referring to an object when in an orientation as shown in the accompanying drawings.

Although specific reference may be made in this text to the use of lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

Although specific reference may be made in this text to embodiments of the invention in the context of a lithographic apparatus, embodiments of the invention may be used in other apparatus. Embodiments of the invention may form part of a mask inspection apparatus, a metrology apparatus, or any apparatus that measures or processes an object such as a wafer (or other substrate) or mask (or other patterning device). These apparatus may be generally referred to as lithographic tools. Such a lithographic tool may use vacuum conditions or ambient (non-vacuum) conditions.

Although specific reference may have been made above to the use of embodiments of the invention in the context of optical lithography, it will be appreciated that the invention, where the context allows, is not limited to optical lithography and may be used in other applications, for example imprint lithography.

Where the context allows, embodiments of the invention may be implemented in hardware, firmware, software, or any combination thereof. Embodiments of the invention may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic storage media; optical storage media; flash memory devices; electrical, optical, acoustical or other forms of propagated signals (e.g. carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc. and in doing that may cause actuators or other devices to interact with the physical world.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims set out below.

1. An apparatus for cleaning a component for use in a lithographic apparatus, the apparatus comprising at least one cleaning module or a plurality of cleaning modules,
wherein the at least one cleaning module or the plurality of cleaning modules comprise a plurality of cleaning mechanisms, and
wherein the plurality of cleaning mechanisms comprise:
at least one preparing mechanism configured to reduce adhesion of the particles to the component and at least one removing mechanism configured to remove particles from the component, or
a plurality of removing mechanisms configured to remove particles from the component.

2. The apparatus of claim 1, wherein the apparatus comprises the plurality of cleaning modules and the apparatus is configured such that the component is passable through the plurality of cleaning modules sequentially to be cleaned.

3. The apparatus of claim 1, wherein the at least one cleaning module or plurality of cleaning modules comprise at least one separation module configured to remove particles from the component.

4. The apparatus of claim 3, wherein the at least one separation module is configured to reduce adhesion of particles to the component, either during or before removing the particles from the component.

5. The apparatus of claim 3, wherein the apparatus comprises the plurality of cleaning modules and wherein the cleaning modules comprise:
a plurality of separation modules, and/or
at least one separation module and at least one preparation module configured to reduce adhesion of particles to the component.

6. The apparatus of claim 1, wherein the at least one cleaning module or plurality of cleaning modules is maintained under a vacuum or controlled gas environment.

7. The apparatus of claim 1, wherein the at least one removing mechanism and/or the at least one preparing mechanism comprises a vacuum generating mechanism.

8. The apparatus of claim 1, wherein the at least one preparing mechanism comprises a heat generating mechanism configured to generate heat to dry the component and/or the particles in a vacuum environment.

9. The apparatus of claim 8, wherein water vapor or other oxygen-containing gasses pressure in the vacuum environment has a pressure below (1E-4 Pa).

10. The apparatus of claim 8, wherein the heat generating mechanism comprises a radiative heater.

11. The apparatus according to claim 8, wherein the heat generating mechanism is configured such that at least one selected from: the radiative heat towards a border of the component is below 1 W/cm²; a border of the component is in contact with a heat sink such that the border temperature remains below 400 C; and/or radiative heat power density at the component is below 10 W/cm².

12. The apparatus according to claim 1, wherein the at least one preparing mechanism comprises a plasma generating mechanism configured to generate a plasma adjacent to or around the component.

13. The apparatus according to claim 12, wherein the plasma generating mechanism is configured to generate plasma with at least one selected from of: a reducing agent, hydrogen, a noble gas, a reducing agent and an oxidizing agent, and/or hydrogen and water.

14. The apparatus according to claim 13, wherein the plasma generating mechanism is configured to generate plasma with a reducing agent and an oxidizing agent and wherein the ratio between reducing agent and oxidizing agent is greater than 100.

15. The apparatus according to claim 12, wherein pressure for plasma generation is in the range of 0.01 Pa to 100 Pa.

16.-40. (canceled)

41. The apparatus according to claim 1, wherein the component is at least one selected from: a pellicle, an EUV transparent film, a dynamic gas lock membrane, or an EUV spectral purity filter.

42. A membrane cleaning apparatus for removing particles from a membrane, the apparatus comprising:
a membrane support configured to support the membrane;
a time-varying electric field generator configured to induce mechanical oscillations in the membrane when supported by the membrane support, to remove particles from the membrane;
at least one displacement sensor configured to measure a displacement of the membrane relative to the membrane at rest when supported by the membrane support; and
a controller configured to determine if the measured displacement of the membrane is outside a predetermined range and control the time-varying electric field generator to alter at least one characteristic of the time-varying electric field if the measured displacement of the membrane is outside the predetermined range.

43. The apparatus of claim 42, wherein the at least one displacement sensor is configured to measure a displacement of at least a localized portion of the membrane relative to the localized portion of the membrane at rest.

44.-50. (canceled)

51. A method of cleaning a component for use in a lithographic apparatus, the method comprising:
cleaning the component in a cleaning module or a plurality of cleaning modules of an apparatus using:
at least one removing mechanism configured to remove particles from the component and at least one preparing mechanism configured to reduce adhesion of the particles to the component, or
a plurality of removing mechanisms configured to remove particles from the component.

52.-54. (canceled)

55. A method of removing particles from a membrane, for use in a lithographic apparatus, the method comprising:
inducing mechanical oscillations in the membrane using a time-varying electric field, to remove particles from the membrane;
measuring a displacement of the membrane relative to the membrane at rest;
determining if the measured displacement of the membrane is outside a predetermined range; and
controlling at least one characteristic of the time-varying electric field if the measured displacement of the membrane is outside the predetermined range.

56.-66. (canceled)
